(19) United States
(12) Patent Application Publication
(10) Pub. No.: US 2026/0136504 A1
(43) Pub. Date: May 14, 2026

(54) Heat Dissipation Devices and Methods of Making and Using Thereof

(71) Applicant: Carbice Corporation, Atlanta, GA (US)

(72) Inventors: Baratunde Cola, Atlanta, GA (US); Craig Green, Atlanta, GA (US)

(21) Appl. No.: 19/386,721

(22) Filed: Nov. 12, 2025

Related U.S. Application Data
(60) Provisional application No. 63/719,506, filed on Nov. 12, 2024.

(51) Int. Cl. H05K 7/20; B33Y 10/00; B33Y 80/00

(52) U.S. Cl. CPC H05K 7/20454; B33Y 10/00; B33Y 80/00; H05K 7/20254

(57) ABSTRACT

Heat dissipation devices and methods of making and using thereof are described herein. Such devices include a substrate having a thermal interfacial material or thermal interfacial coating on a surface of the substrate and a heat dissipation structure directly contacting an opposing surface of the substrate. Such heat dissipation devices have applications in thermal management of heat-generating devices or sources.

### CROSS-REFERENCE TO RELATED APPLICATIONS

This application claims benefit of U.S. Provisional Application No. 63/719,506, filed Nov. 12, 2024, is hereby incorporated herein by reference in its entirety.

### FIELD OF THE INVENTION

This invention is in the field of devices for dissipating heat away from a heat source, as well as methods of making and using thereof.

### BACKGROUND OF THE INVENTION

Thermal interface materials (TIMs) are used to enhance heat transfer between a heat sink and a heat source by filling microscopic gaps between the surfaces. TIMs, however, suffer from several limitations.

In one example, TIMs can add thermal resistance when placed between a heat sink and a heat source particularly if the TIM layer is too thick, which can reduce the efficiency of heat transfer and diminish the overall cooling performance thereof. Application variability is another challenge with TIMs. Achieving a thin layer is important for optimal performance, but uneven application can result in air pockets or overly thick areas, creating “hot spots” where heat transfer is less effective. In some cases, TIMs can also suffer from a “pumping out” effect, where thermal cycling (repeated heating and cooling) can cause them to shift or “pump out” from between the surfaces, leaving gaps that worsen heat transfer.

While TIMs are important for bridging the gap between a heat sink and a heat source, factors, such as those named above, highlight the need for heat dissipation devices which can address these shortcomings.

Therefore, it is an object of the present invention to provide heat dissipation devices which address the limitations discussed above.

It is a further object of the present invention to provide methods of making such heat dissipation devices.

It is still a further object of the present invention to provide methods of using such heat dissipation devices.

### SUMMARY OF THE INVENTION

Heat dissipation devices, and methods of making and using thereof, are described where such heat dissipation devices can be contacted to heat-generating devices to provide improved thermal management.

In one non-limiting instance, a heat dissipation device includes:
a substrate including a first surface and a second surface, which are on opposing sides of the substrate;
a thermal interfacial material or thermal interfacial coating in direct contact with at least part of the first surface; and
a heat dissipation structure in direct contact with the second surface;
wherein thermal resistance between the substrate, the thermal interfacial material or thermal interfacial coating, and the heat dissipation structure is in a range from between about 0.01 to 0.1 cm² ° C./W, or individual values or sub-ranges contained within the aforementioned range.

Such heat dissipation devices can be formed according to a method including the steps of:
(a) forming a thermal interfacial material or a thermal interfacial coating in direct contact onto a first surface of a substrate; and
(b) forming or bonding a heat dissipation structure in direct contact onto a second surface of the substrate;
wherein the first surface and the second surface are on opposing sides of the substrate;
wherein thermal resistance between the substrate, the thermal interfacial material or thermal interfacial coating, and the heat dissipation structure is in a range from between about 0.01 to 0.1 cm² ° C./W, or individual values or sub-ranges contained within the aforementioned range.

In another non-limiting example, a method of making a heat dissipation device can includes the steps of:
(a′) providing a substrate comprising a thermal interfacial material or a thermal interfacial coating in direct contact with a first surface of a substrate; and
(b′) forming or bonding a heat dissipation structure in direct contact onto a second surface of the substrate;
wherein the first surface and the second surface are on opposing sides of the substrate;
wherein thermal resistance between the substrate, the thermal interfacial material or thermal interfacial coating, and the heat dissipation structure is in a range from between about 0.01 to 0.1 cm² ° C./W, or individual values or sub-ranges contained within the aforementioned range.

Such heat dissipation devices are suited for applications where the heat dissipation devices are contacted to heat-generating devices or sources. In one non-limiting instance, a method of dissipating heat can include the steps of:
(i) contacting a heat dissipation device, such as those described herein, to a heat source;
wherein the heat dissipation device increases dissipation of heat generated by the heat source by at least about 10%. In some instances, the heat dissipation device increases dissipation of heat generated by the heat source by at least about 20%, 30% 40%, 50%, 60%, 70%, 80%, 90%, or greater.

In some instances, the heat source (heat generating device) is selected from the group consisting of a microchip, microprocessors (CPU), graphics processing unit (GPU), power transistors, light-emitting diodes, battery packs, power supplies, power converters, radio frequency amplifiers, electric motors, electronic inverters, laser diodes, and optoelectronic devices.

### BRIEF DESCRIPTION OF THE DRAWINGS

FIG. 1A shows a non-limiting cross-sectional view of a heat dissipation device 100 according to an embodiment described that includes a substrate 110 having a thermal interfacial material or thermal interfacial coating 120 directly on one surface of the substrate and a heat dissipation structure 130 directly contacting an opposite surface of the substrate.

FIG. 1B shows a non-limiting cross-sectional view of a heat dissipation device 100 according to an embodiment described that includes a heat dissipation structure 130 directly contacting a surface of substrate 110 having a thermal interfacial material or thermal interfacial coating 120 directly on one surface of the substrate, where the heat dissipation structure includes a non-planar or contoured region 140 intended to match to one or more non-planar surfaces or curvatures present on a heat source.

FIG. 1C shows a non-limiting cross-sectional view of a heat dissipation device 100 according to an embodiment described that includes a substrate 110 having a thermal interfacial material or thermal interfacial coating 120 directly on one surface of the substrate and a heat dissipation structure 130, which formed from or includes a compressible gap filling material with modulus thermal conductivity tuned through a deposited geometry, directly contacting an opposite surface of the substrate.

FIG. 1D shows a non-limiting cross-sectional view of a heat dissipation device 100 according to an embodiment described that includes a substrate 110 having a thermal interfacial material or thermal interfacial coating 120 directly on one surface of the substrate and a heat dissipation structure 130, which includes a compressible or conformable layer 150 with modulus thermal conductivity tuned through a deposited geometry, directly contacting an opposite surface of the substrate.

FIG. 1E shows a non-limiting cross-sectional view of a heat dissipation device according to an embodiment described that includes a substrate 110 having a thermal interfacial material or thermal interfacial coating 120 directly on one surface of the substrate and a heat dissipation structure 130 directly contacting an opposite surface of the substrate, where the heat dissipation structure includes contouring or non-planar features, such as pillars 135, which can minimize an interface bond to another surface (such as a heat-generating device surface).

FIG. 2A shows a non-limiting cross-sectional view of a heat dissipation device according to an embodiment described that includes two substrates 110′ having thermal interfacial material or thermal interfacial coatings 120′ directly on a surface of each of the respective substrates and a heat dissipation structure 130′ directly contacting an opposite surface of the substrate.

FIG. 2B shows a non-limiting cross-sectional view of a heat dissipation device according to an embodiment described that includes multiple substrates 110′ having multiple thermal interfacial material or thermal interfacial coatings 120′ directly on one surface of each respective substrate and a heat dissipation structure 130′ directly contacting an opposite surface of each of the respective substrates, where the heat dissipation structure includes contouring or non-planar features, such as pillars, which can minimize an interface bond to another surface (such as a heat-generating device surface).

FIG. 2C shows a non-limiting cross-sectional view of a heat dissipation device according to an embodiment described that includes a multiple substrates 110′ each having thermal interfacial material or thermal interfacial coatings 120′ directly on one surface of each respective substrate and a heat dissipation structure 130′ directly contacting an opposite surface of each of the respective substrates, where the heat dissipation structure includes contouring or non-planar features, such as pillars, which can minimize an interface bond to another surface (such as a heat-generating device surface).

FIG. 2D shows a non-limiting cross-sectional view of a heat dissipation device according to an embodiment described that includes a substrate 110′ having a thermal interfacial material or thermal interfacial coating 120′ directly on one surface of the substrate and a heat dissipation structure 130′ directly contacting an opposite surface of the substrate, where the heat dissipation structure includes a cold plate structure 140′ having, for example, fins, wicks, or spreaders present.

FIG. 3 shows a non-limiting cross-sectional view of a heat dissipation device on a pre-form or build plate 150.

FIG. 4A shows a non-limiting exemplary method flow wherein a substrate (left) has a thermal interfacial material or a thermal interfacial coating formed on one surface of the substrate (center) and a heat dissipation structure is formed directly on an opposite surface of the substrate (right).

FIG. 4B shows a non-limiting exemplary method flow wherein a substrate (left) has a thermal interfacial material or a thermal interfacial coating formed on one surface of the substrate (center) and a heat dissipation structure (either formed or provided separately as a free standing structure) is bonded directly onto an opposite surface of the substrate (right).

FIG. 4C shows a non-limiting exemplary method flow wherein a substrate having a thermal interfacial material or a thermal interfacial coating already formed on a surface of the substrate is provided or obtained instead of manufactured (left) and a heat dissipation structure is formed directly on an opposite surface of the substrate (right).

FIG. 4D shows a non-limiting exemplary method flow wherein a substrate having a thermal interfacial material or a thermal interfacial coating already formed on a surface of the substrate is provided or obtained instead of manufactured (left) and a heat dissipation structure (either formed or provided separately as a free standing structure) is bonded directly on an opposite surface of the substrate (right).

FIG. 5 shows a non-limiting exemplary process of joining two heat dissipation devices by bonding their respective heat dissipation structures via a suitable bonding technique to afford a heat dissipation device that includes two substrates having thermal interfacial material or thermal interfacial coatings directly on a surface of each of the respective substrates and a single bonded heat dissipation structure directly contacting an opposite surface of the substrate.

FIG. 6 shows a non-limiting exemplary method flow wherein a substrate having a thermal interfacial material or a thermal interfacial coating already formed on a surface of the substrate is provided or obtained and a heat dissipation structure (either formed or provided separately as a free standing structure) is bonded directly on an opposite surface of the substrate (right), and a cold plate structure having, for example, fins, wicks, or spreaders is formed atop the heat dissipation structure.

FIG. 7 shows a non-limiting cross-sectional view of a heat dissipation device according to an embodiment described that includes contouring or non-planar features, such as pillars 135, which are contacted to a heat-generating device or source formed of chiplets on an interposer.

FIG. 8 shows a non-limiting cross-sectional view of a heat dissipation device according to an embodiment described having a stepped/tiered structure to minimize bond line thickness to a 3D power chiplet system.

FIG. 9 shows a non-limiting cross-sectional view of a heat dissipation device according to an embodiment having a cold plate structure integrated into the monolithic device.

FIG. 10A shows an image of an exemplary thermal test vehicle (TTV) with exemplary power maps for evaluating heat dissipation devices.

FIG. 10B shows a unit cell of a utility silicon chiplet with in situ temperature sensing and heating elements for evaluating heat dissipation devices.

FIG. 11A shows a non-limiting cross-sectional view of a heat dissipation device including a metal block, such as copper block, as a heat dissipation structure, which is contacted to a separate cold plate that is contacted to a vapor chamber.

FIG. 11B shows a non-limiting cross-sectional view of a heat dissipation device including an integrated cold plate structure contacted to a vapor chamber.

FIG. 11C shows a non-limiting cross-sectional view of a heat dissipation device including a metal block, such as a copper block, as a heat dissipation structure and further include an integrated cold plate structure atop which includes structures, such as fins, wicks, or spreaders, which can act as boiling surface structures and is contacted to a vapor chamber.

### DETAILED DESCRIPTION OF THE INVENTION

Described herein are heat dissipation devices and methods of making and using thereof. Such heat dissipation devices can be contacted to heat-generating devices to provide improved thermal management.

### I. Definitions

“Thermal Interface Material” (TIM), as used herein, refers to a material or combination of materials that provide high thermal conductance and mechanical compliance between a heat source and heat sink or spreader to effectively conduct heat away from a heat source.

“Bond line thickness” (BLT), as used herein, refers to the thickness of the bond line between two interfacing surfaces, which is relevant to heat transfer efficiency. A thinner BLT reduces the distance heat must travel to be removed from a heat source, thereby improving thermal performance.

“Conformable,” “Compliant,” or “Compliance,” as used herein, refers to the ability of a material to conform when contacted to one or more surfaces such that efficient conformance to the asperities of the adjoining surface results in sufficient or high contact areas at the interfaces between the surfaces and the material.

“Compressible,” as used herein, refers to the ability of a material to deform (reduce in thickness) under applied pressure-such as the clamping or mounting force used when assembling electronic components such as CPUs, GPUs, or power modules to heat sinks or cold plates.

“Flexible,” refers to a material's ability to conform to the surfaces it contacts, such as for filling in microscopic gaps, irregularities, or uneven surfaces on to which it is contacted to.

“Interdigitation” or “Interdigitating”, as used herein, refers to the ability and or degree which one or more individual nanostructure elements of an array or sheet to infiltrate or penetrate into the adjacent nanostructure elements of another array or sheet when the two different arrays or sheets are contacted or stacked.

“Carbon Nanotube Array” or “CNT array” or “CNT forest”, as used herein, refers to a plurality of carbon nanotubes which are vertically aligned on a surface of a material. Carbon nanotubes are said to be “vertically aligned” when they are substantially perpendicular to the surface on which they are supported or attached. Nanotubes are said to be substantially perpendicular when they are oriented on average within 30, 25, 20, 15, 10, or 5 degrees of the surface normal.

“Carbon Nanotube Sheet” or “CNT sheet”, as used herein, refers to a plurality of carbon nanotubes which are aligned in plane to create a free-standing sheet. Carbon nanotubes are said to be “aligned in plane” when they are substantially parallel to the surface of the sheet that they form. Nanotubes are said to be substantially parallel when they are oriented on average greater than 40, 50, 60, 70, 80, or 85 degrees from sheet surface normal.

“Coating material” as used herein, generally refers to polymers and/or molecules that can bond to CNTs through van der Waals bonds, I-x stacking, mechanical wrapping and/or covalent bonds and bond to metal, metal oxide, or semiconductor material surfaces through van der Waals bonds, I-x stacking, and/or covalent bonds.

Numerical ranges disclosed in the present application include, but are not limited to, ranges of temperatures, ranges of pressures, ranges of molecular weights, ranges of integers, ranges of conductance and resistance values, ranges of times, and ranges of thicknesses. The disclosed ranges of any type, disclose individually each possible number that such a range could reasonably encompass, as well as any sub-ranges and combinations of sub-ranges encompassed therein. For example, disclosure of a pressure range is intended to disclose individually every possible temperature value that such a range could encompass, consistent with the disclosure herein.

Use of the term “about” is intended to describe values either above or below the stated value, which the term “about” modifies, in a range of approx. +/−10%; in other instances, the values may range in value either above or below the stated value in a range of approx. +/−5%. When the term “about” is used before a range of numbers (i.e., about 1-5) or before a series of numbers (i.e., about 1, 2, 3, 4, etc.) it is intended to modify both ends of the range of numbers or each of the numbers in the series, unless specified otherwise.

### II. Heat Dissipation Devices

Described herein are devices for heat dissipation or thermal communication between a source of heat and a secondary body (such as a heat dissipation structure) where the heat dissipation device is formed directly onto a substrate of a material designed to minimize interfacial resistance between the heat source, such as a heat-generating device, and the secondary body.

In one non-limiting instance, a heat dissipation device includes:
a substrate including a first surface and a second surface, which are on opposing sides of the substrate;
a thermal interfacial material or thermal interfacial coating in direct contact with at least part of the first surface; and
a heat dissipation structure in direct contact with the second surface;
wherein thermal resistance between the substrate, the thermal interfacial material or thermal interfacial coating, and the heat dissipation structure is in a range from between about 0.01 to 0.1 cm² ° C./W, or individual values or sub-ranges contained within the aforementioned range.

The substrate having the thermal interfacial material or thermal interfacial coating on one surface of the substrate can be considered to form a thermal interface material (TIM), which has a heat dissipation structure directly formed/bonded onto the opposing surface of the substrate. Typically, the thermal interfacial material or thermal interfacial coating is interfaced or contacted to a heat-generating device.

Typically, the heat dissipation structure forms an interface-free bond with the second surface. An “interface-free bond” refers to a bond between two materials or surfaces that is created without an intermediary layer or gap between them. This type of interface-free bond achieves direct material-to-material contact, allowing for maximal interaction, such as thermal conductivity, across the joined surfaces without any interruption or significant interruption caused by an interface or bonding material (like adhesives or thermal pastes). Alternately the bond may be comprised of an interstitial material that creates an alloy, ceramic or other bonded structure with the intersecting surface, minimizing phonon scattering at the boundary between the two surfaces.

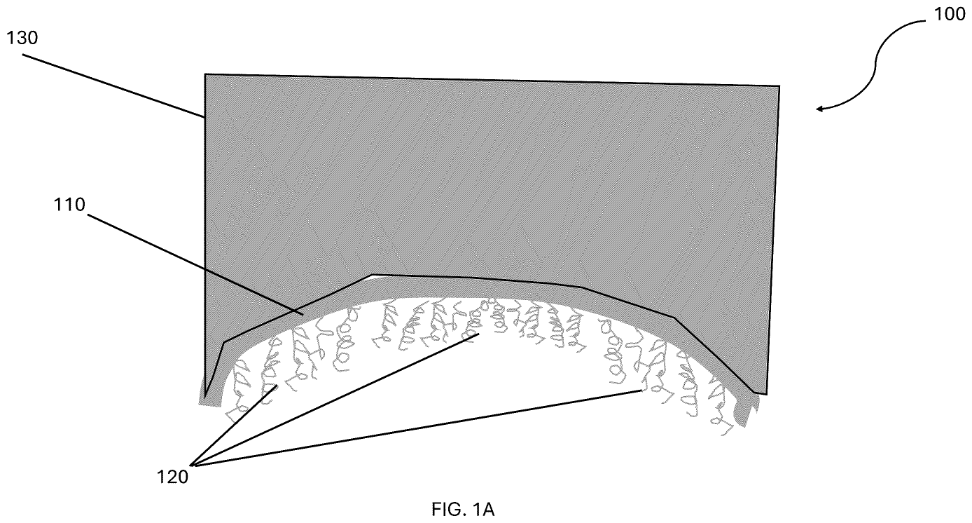

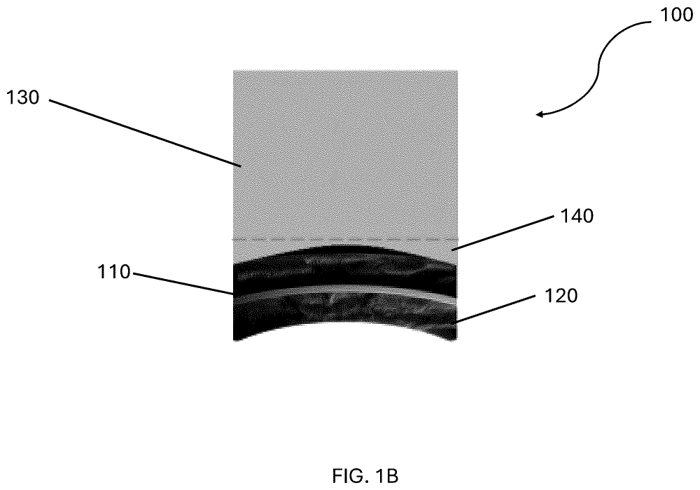

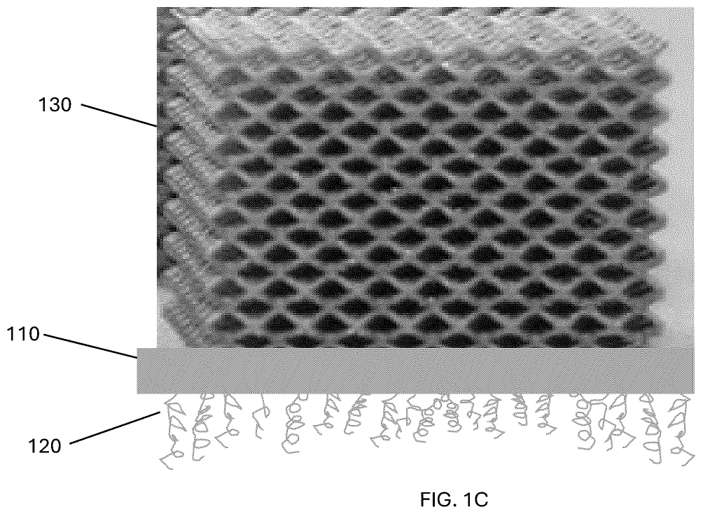

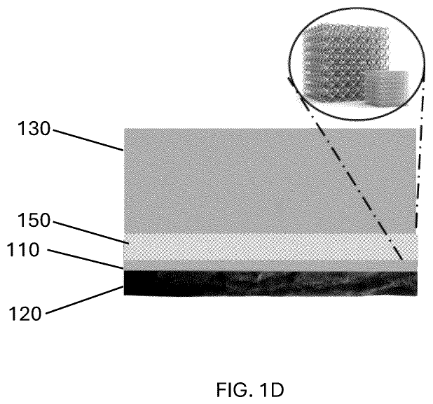

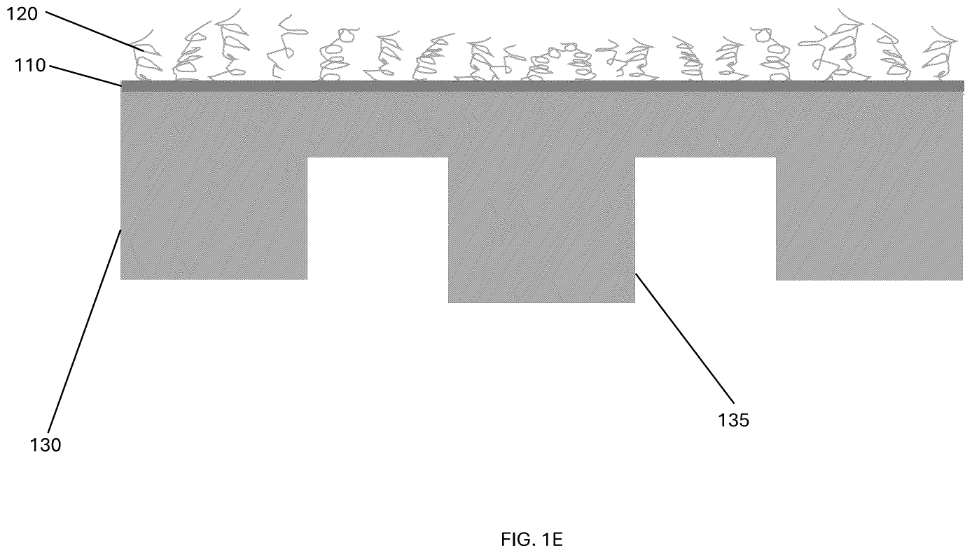

In one instance, as shown in FIG. 1A, a non-limiting cross-sectional view of a heat dissipation device 100 according to an embodiment described includes a substrate 110 having a thermal interfacial material or thermal interfacial coating 120 directly on one surface of the substrate and a heat dissipation structure 130 directly contacting an opposite surface of the substrate. In other instances of a heat dissipation device, FIG. 1B shows a non-limiting cross-sectional view of a heat dissipation device 100 according to an embodiment described that includes a heat dissipation structure 130 directly contacting a surface of substrate 110 having a thermal interfacial material or thermal interfacial coating 120 directly on one surface of the substrate, where the heat dissipation structure includes a non-planar or contoured region 140 intended to match to one or more non-planar surfaces or curvatures present on a heat source. In yet another non-limiting example of a heat dissipation device, FIG. 1C shows a non-limiting cross-sectional view of a heat dissipation device 100 according to an embodiment described includes a substrate 110 having a thermal interfacial material or thermal interfacial coating 120 directly on one surface of the substrate and a heat dissipation structure 130, which is a compressible gap filling material with modulus thermal conductivity tuned through a deposited geometry, directly contacting an opposite surface of the substrate. In still another non-limiting example of a heat dissipation device, FIG. 1D shows a non-limiting cross-sectional view of a heat dissipation device 100 according to an embodiment described that includes a substrate 110 having a thermal interfacial material or thermal interfacial coating 120 directly on one surface of the substrate and a heat dissipation structure 130, which includes a compressible or conformable layer 150 with modulus thermal conductivity tuned through a deposited geometry, directly contacting an opposite surface of the substrate. The compressible gap filling material or compressible or conformable layer shown in FIGS. 1C and 1D can be formed from a lattice structure, such as a metal lattice structure that provides local modulus reduction and is able to conform to one or more non-planar surfaces or curvatures present on a heat source when compressed thereon. The compressible or conformable layer can have any suitable thickness, such as in a range from between about 5 um-100 um, or up to about 500 um, 1000 um, 2000 um, or up to 3 mm, as well as individual values or subranges contained within the aforementioned values. In yet another example, FIG. 1E shows a non-limiting cross-sectional view of a heat dissipation device according to an embodiment described that includes a substrate 110 having a thermal interfacial material or thermal interfacial coating 120 directly on one surface of the substrate and a heat dissipation structure 130 directly contacting an opposite surface of the substrate, where the heat dissipation structure includes contouring or non-planar features, such as pillars 135, which can minimize an interface bond to another surface (such as a heat-generating device surface).

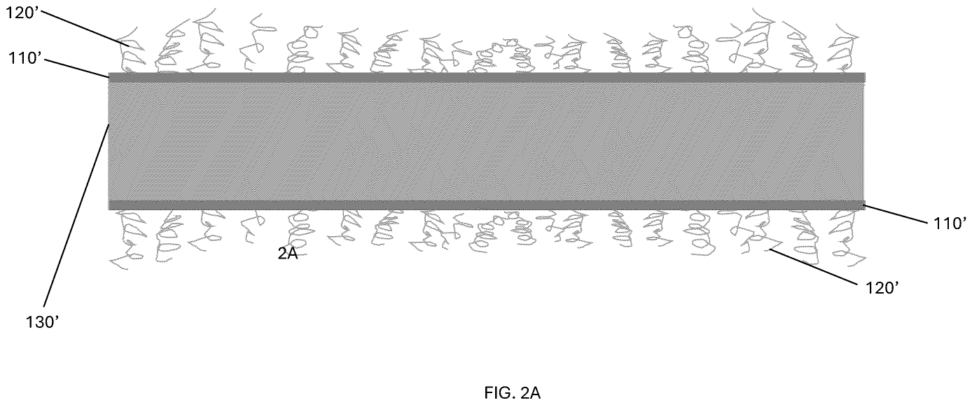

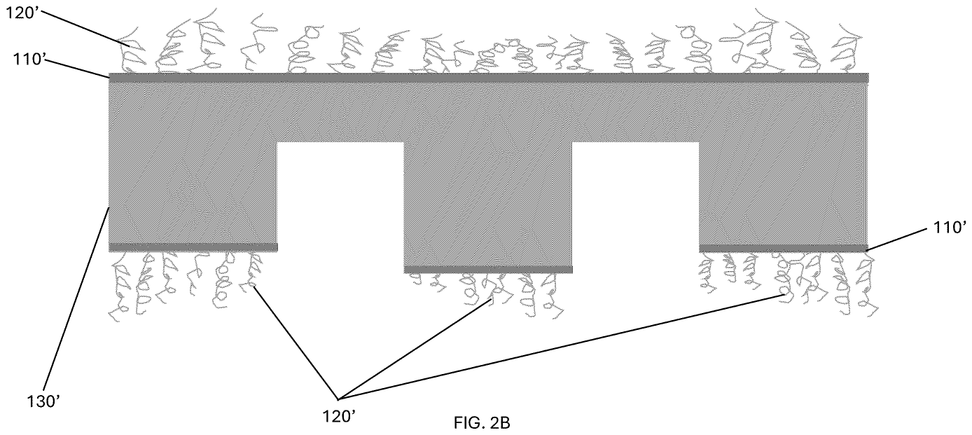

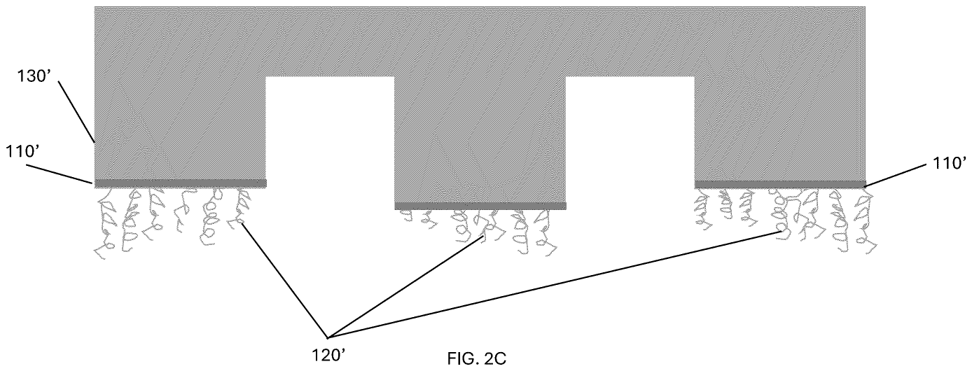

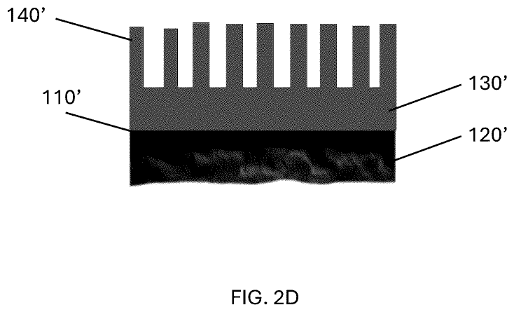

In some other instances, a heat dissipation device may include two substrates having thermal interfacial material or thermal interfacial coatings on a surface of each respective substrate and a heat dissipation structure in between contacts the opposing surfaces of the two respective substrates. See, for example, FIG. 2A which shows a non-limiting cross-sectional view of a heat dissipation device according to an embodiment described that includes a two substrates 110′ having thermal interfacial material or thermal interfacial coatings 120′ directly on a surface of each of the respective substrates and a heat dissipation structure 130′ directly contacting an opposite surface of the substrate. In yet another non-limiting example, FIG. 2B shows a non-limiting cross-sectional view of a heat dissipation device according to an embodiment described that includes multiple substrates 110′ having multiple thermal interfacial material or thermal interfacial coatings 120′ directly on one surface of each respective substrate and a heat dissipation structure 130 directly contacting an opposite surface of each of the respective substrates, where the heat dissipation structure includes contouring or non-planar features, such as pillars, which can minimize an interface bond to another surface (such as a heat-generating device surface). In still another non-limiting example, FIG. 2C shows a non-limiting cross-sectional view of a heat dissipation device according to an embodiment described that includes a multiple substrates 110′ each having thermal interfacial material or thermal interfacial coatings 120′ directly on one surface of each respective substrate and a heat dissipation structure 130′ directly contacting an opposite surface of each of the respective substrates, where the heat dissipation structure includes contouring or non-planar features, such as pillars, which can minimize an interface bond to another surface (such as a heat-generating device surface). In yet another non-limiting example, FIG. 2D shows a non-limiting cross-sectional view of a heat dissipation device according to an embodiment described that includes a substrate 110′ having a thermal interfacial material or thermal interfacial coating 120′ directly on one surface of the substrate and a heat dissipation structure 130′ directly contacting an opposite surface of the substrate, where the heat dissipation structure includes a cold plate structure 140′ with fins, wicks, or spreaders present.

As noted below, such heat dissipation devices are made by forming or bonding a heat dissipation structure directly on the substrate having the thermal interfacial material or thermal interfacial coating in order to eliminate the interfacial resistance that would otherwise exist between the TIM and the heat dissipation structure. Thus, the heat dissipation structure, substrate, and thermal interfacial material or thermal interfacial coating of the device are combined into a single structure which is effective at reducing the overall resistance to heat transfer by a factor of about 2, as compared to when the TIM alone (substrate having thermal interfacial material or thermal interfacial coating thereon) is placed in between a heat source and a heat dissipation structure which is not bonded onto the TIM which adds an additional interface between the TIM and the heat dissipation structure which increases resistance to heat transfer.

Typically, by forming or bonding the heat dissipation structure directly onto the substrate on which the thermal interface material or coating is on it is also possible to reduce the need for the TIM material to have to compress to comply with the curvature of a mating surface, such as of a heat-generating device. Thus, the heat dissipation structure can be formed onto the TIM substrate such that the as-made heat dissipation structure matches the curvature of the heat generating/source device thereby reducing the need for compression of the interfacing material which allows for the thickness of the interface to be reduced, further reducing interface resistance.

In some instances, the heat dissipation devices described are conformable and/or flexible, such that the substrate, thermal interfacial material or thermal interfacial coating, and heat dissipation structure are all conformable or compliant. The heat dissipation device can conform to a mating surface of a heat-generating device (heat source) onto which it is contacted and can elastically deform or deflect under an installation force to conform thereto. The heat dissipation device can conform to flat, non-flat, undulating, or other uniform or non-uniform surface shapes and provide a good thermal interface independent of the heat-generating device surface flatness or surface topology. In most instances, the heat dissipation device can conform to contact all of the desired surface of a heat-generating device which is to be contacted with the heat heat-generating or substantially all of the surface (i.e., at least about 75%, 80%, 85%, 90%, 91%, 92%, 93%, 94%, 95%, 96%, 97%, 98%, or 99%, or higher).

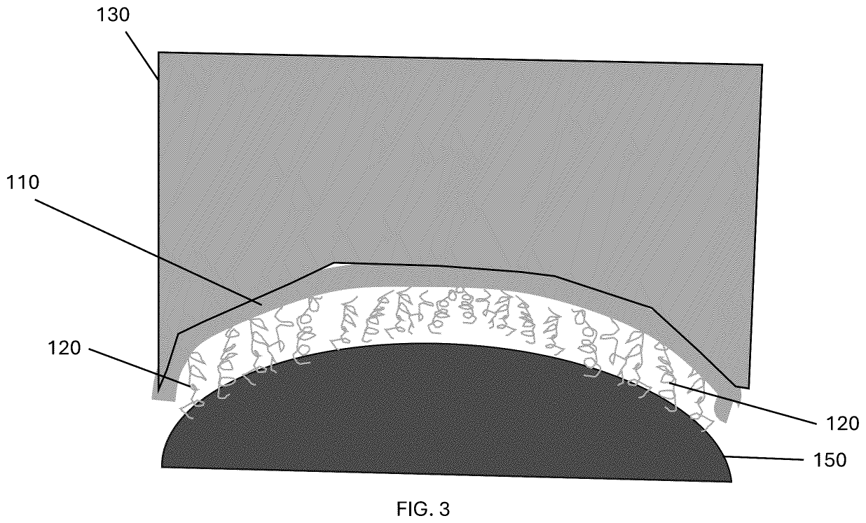

In some other instances, the heat dissipation devices are formed on a pre-form or build plate which imparts a desired shape or form (i.e., curvature) to the heat dissipation formed onto the TIM substrate such that the as-made heat dissipation structure matches the shape or form of a mating surface of a heat generating/source device. Thus, a pre-form or build plate can be used which has the shape or form (i.e., curvature) of a mating surface of a heat generating/source device. Thus, the resulting heat dissipation device can be tailored and easily mated onto the mating surface of the heat generating/source device. See FIG. 3 which shows a non-limiting cross-sectional view of a heat dissipation device on a pre-form or build plate 150.

The inclusion of non-planar or contoured region(s) in the heat dissipation devices, such as shown in non-limiting FIGS. 1A, 1B, 1E, 2B, and 2C allows for matching and conforming to intersecting surfaces on a heat source or heat generating device (such as a chip or die) which may have complex topology. Such non-planar or contoured region(s) allow for the bond line thickness of the thermal interfacial material or thermal interfacial coating contacted to the heat source or heat generating device to be minimized by ensuring that interfaces are and remain thin (i.e., “thin” can refer to a BLT of less than about 2 microns, 1.5 microns, 1 micron, 750 nm, 500 nm, 250 nm, 100 nm; or in a range between about 50 nm to 2 microns, 50 nm to 1 micron, 100 nm to 2 microns, 100 nm to 1 micron, or 100 nm to 500 nm, as well as individual values or subranges within the aforementioned ranges.

Typically, the heat dissipation device contacts the mating surface of a heat source, such as a heat-generating device, and provides intimate contact between the thermal interfacial material or thermal interfacial coating and the mating surface. The conformability and/or tailored shape of the device can be used to allow for the exclusion of components, such as pads, epoxies, greases, pastes, etc.) at the mating surface between the heat-generating surface(s) of a device and the heat dissipation device.

In some instances, the first surface of the heat dissipation devices include one or more non-planar features thereon to be able to contact or maximize contact to one or more non-planar surfaces or curvatures present on a heat source; and at least the one or more non-planar features include the thermal interfacial material or thermal interfacial coating thereon. See, for example, FIG. 2C.

In some instances, the first surface of the heat dissipation devices is contoured to contact or maximize contact to one or more non-planar surfaces or curvatures present on a heat source.

In some instances, such non-planar surfaces or curvatures on the heat source include ovoid, concave, saddle point, and/or stepwise features. Other non-planar surface features or curvatures are possible depending on the heat source onto which the heat dissipation device is contacted to. In some instances, the one or more non-planar surfaces or curvatures on the heat source result from warpage during operation of the heat source and the thermal interfacial material or thermal interfacial coating remains in full contact or substantially in contact with the one or more non-planar surfaces or curvatures on the heat source during operation.

“Substantially in contact,” refers to at least about 90%, 91%, 92%, 93%, 94%, 95%, 96%, 97%, 98%, 99%, 99.1%, 99.2%, 99.3%, 99.4%, 99.5%, 99.6%, 99.7%, 99.8%, 99.9%, or more, of the surface area of the one or more non-planar surfaces or curvatures on the heat source are in contact with the thermal interfacial material or thermal interfacial coating of the device.

As noted above, the heat source, such as heat generating device, can have one or more non-planar surfaces or curvatures that are in contact with the heat dissipation device. Such non-planar surfaces or curvatures may include ovoid, concave, saddle point, and/or stepwise features.

In some instances, the heat dissipation device has a total thermal resistance, across all components forming the device, which is in a range from between about 0.01 to 0.1 cm² ° C./W, or individual values or sub-ranges contained within the aforementioned range.

In some instances, the thermal resistance of the heat dissipation device is reduced by at least about 25%, 30%, 35%, 40%, 45%, 50%, 55%, 60%, 65%, 70% or greater when the heat dissipation structure is formed or bonded directly onto a surface of a substrate which has a thermal interfacial material or thermal interfacial coating on the opposing side, as described herein, when measured, for example, using structure function analysis. In certain instances, the heat dissipation device exhibits thermal resistances of less than about 0.5, 0.4, 0.3, 0.2, 0.1, 0.05, or 0.02 cm² K/W. In certain instances, the heat dissipation device exhibits thermal resistances of between about 0.5 and 0.01 cm² K/W, or individual values or sub-ranges contained within. In some instances, the thermal resistance is about 0.5, 0.4, 0.3, 0.2, 0.1, 0.05, or 0.02 cm² K/W.

In one instance, the apparent thermal conductivity of the heat dissipation device is increased by at least about 25%, 30%, 35%, 40%, 45%, 50%, 55%, 60%, 65%, 70% or greater as compared to when the heat dissipation structure is neither formed or bonded directly onto a surface of a substrate having a thermal interfacial material or thermal interfacial coating on the opposing side and the heat dissipating structure is independent of the TIM. In some instances, the heat dissipation devices exhibit conductance values in the range of about 1-2500 W/m-K, 1-2000 W/m-K, 1-1500 W/m-K, 1-1000 W/m-K, 1-500 W/m-K, 5-500 W/m-K, 5-400 W/m-K, 5-300 W/m-K, 5-200 W/m-K, 5-150 W/m-K, 5-100 W/m·K, or 3-30 W/m-K.

### A. Substrate

The substrate is typically a planar and inert substrate having two surfaces on opposing sides. Moreover, the substrate can be said to be a growth substrate or deposition substrate onto which is formed a thermal interfacial material or thermal interfacial coating, as described below, and together form a TIM which forms part of the heat dissipation devices described in detail above.

In some instances, the substrate is a foil, such as a metal foil which can be made of aluminum or copper. In some other instances the substrate is made of diamond, AlSiC, Si, Silver Diamond, CuW, Cu Diamond, CuMo, graphite, alumina, AlN, Mo, MgSiC, steel, Ni, Ti, bronze, brass, Sn, Si, SiC, GaN, SiO₂, BN, or GaAs.

In some instances, the substrate has a thickness in range from between about 10 um to 6 mm, 50-500 um, 100-1000 um, or 100 to 5,000 um; or an individual thickness or subrange contained within the aforementioned ranges.

### B. Thermal Interfacial Material or Thermal Interfacial Coating

The thermal interfacial material or thermal interfacial coating are present on the substrate. In some instances, the thermal interfacial material or thermal interfacial coating includes a plurality of carbon nanostructures, such as carbon nanotubes. In some instances, the plurality of carbon nanostructures is formed from a carbon nanotube array supported on, or attached to, the surface of the substrate/support, as described below. In some cases, the thermal interfacial material or thermal interfacial coating is formed of a single-tiered or single layered carbon nanotube array or carbon nanotube sheet. In certain other instances, the carbon nanotube arrays or sheets described below can be stacked, according to the methods described, to afford multilayered or multitiered structures, as described in further detail below. For thermal interfacial material or thermal interfacial coating formed from such single or multilayered or multitiered structures, these may demonstrate good compliance, i.e., the ability to conform when contacted to one or more surfaces of heat-generating device(s) (such as a die or chip).

In some other instances, the thermal interfacial material or thermal interfacial coating includes a plurality of nanostructures, such as carbon nanotubes (CNTs), boron-nitride nanotubes (BNNTs), Si nanowires, Cu nanowires, carbon (nano)fibers, nanosprings, or combinations thereof.

In some instances, the thermal interfacial material or thermal interfacial coating has a thickness in range from between about 5 um-100 um, or up to about 500 um, 1000 um, 2000 um, and sometimes up to 3 mm; or an individual thickness or subrange contained within the aforementioned ranges.

a. Carbon Nanotube Arrays

Carbon nanotube (CNT) arrays are described herein contain a plurality of carbon nanotubes supported on, or attached to, the surface of an inert substrate/support, such as a metallic (e.g., Al or Au) foil, metal alloys (i.e., steel). In some cases, the substrate/support can be a flexible, electrically, and thermally conductive substrate, such as graphite or other carbon-based material. The CNT arrays can be formed using the methods described below.

Typically, the CNTs are vertically aligned on the substrate/support. CNTs are said to be “vertically aligned” when they are substantially perpendicular to the surface on which they are supported or attached. Nanotubes are said to be substantially perpendicular when they are oriented on average within 30, 25, 20, 15, 10, or 5 degrees of the surface normal. Generally, the carbon nanotubes are present at a sufficient density such that the nanotubes are self-supporting and adopt a substantially perpendicular orientation to the surface of the substrate. Preferably, the nanotubes are spaced at optimal distances from one another and are of uniform height to minimize thermal transfer losses, thereby maximizing their collective thermal diffusivity.

The CNT arrays contain nanotubes which are continuous from the top of the array (i.e., the surface formed by the distal end of the carbon nanotubes when vertically aligned on the substrate) to bottom of the array (i.e., the surface of the substrate). The CNT array may be formed from multi-wall carbon nanotubes (MWNTs), which generally refers to nanotubes having between approximately 4 and approximately 10 walls. The array may also be formed from few-wall nanotubes (FWNTs), which generally refer to nanotubes containing approximately 1-3 walls. FWNTs include single-wall carbon nanotubes (SWNTs), double-wall carbon nanotubes (DWNTS), and triple-wall carbon nanotubes (TWNTs). In certain instances, the nanotubes are MWNTs. In some instances, the diameter of MWNTs in the arrays ranges from 10 to 40 nm, 15 to 30 nm, or about 20 nm. The length of CNTs in the arrays can range from 1 to 5,000 micrometers, 5 to 5000 micrometers, preferably 5 to 2500 micrometers, 5 to 2000 micrometers, or 5 to 1000 micrometers. In some instances, the length of CNTs in the arrays can range from 1-500 micrometers or 1-100 micrometers.

The CNTs display strong adhesion to the substrate surface on which they are formed. In certain cases, the CNT array will remain substantially intact after being immersed in a solvent, such as ethanol, and sonicated for a period of at least five minutes. In particular cases, at least about 90%, 95%, 96%, 97%, 98%, 99%, or 99.9% of the CNTs remain on the surface after sonication in ethanol.

b. Carbon Nanotube Sheets

Carbon nanotube sheets are also described herein. Such CNT sheets can be bonded onto a substrate surface and a heat dissipation structure may be formed or bonded onto the opposite surface. The sheets contain a plurality of carbon nanotubes that support each other through strong van der Waals force interactions and mechanical entanglement to form a freestanding material.

CNT sheets can be formed using the methods described below. The CNTs form a freestanding sheet and are aligned in plane with the surface of this sheet. CNTs are said to be “aligned in plane” when they are substantially parallel to the surface of the sheet that they form. Nanotubes are said to be substantially parallel when they are oriented on average greater than 40, 50, 60, 70, 80, or 85 degrees from sheet surface normal.

Generally, the nanotubes are present at a sufficient density such that the nanotubes are self-supporting and adopt a substantially parallel orientation to the surface of the sheet.

Preferably, the nanotubes are spaced at optimal distances from one another and are of uniform length to minimize thermal transfer losses, thereby maximizing their collective thermal diffusivity.

The CNT sheets may be formed from multi-wall carbon nanotubes (MWNTs), which generally refers to nanotubes having between approximately 4 and approximately 10 walls. The sheets may also be formed from few-wall nanotubes (FWNTs), which generally refers to nanotubes containing approximately 1-3 walls. FWNTs include single-wall carbon nanotubes (SWNTs), double-wall carbon nanotubes (DWNTS), and triple-wall carbon nanotubes (TWNTs). In certain instances, the nanotubes are MWNTs. In some instances, the diameter of MWNTs in the arrays ranges from 10 to 40 nm, 15 to 30 nm, or about 20 nm. The length of CNTs in the sheets can range from 1 to 5,000 micrometers, 100 to 5000 micrometers, 500 to 5000 micrometers, or 1000 to 5000 micrometers. In some instances, the length of CNTs in the sheets can range from 1-500 micrometers or 1-100 micrometers.

### 1. Coating(s)/Coating Materials

The CNT array or sheet can include a coating material which adheres or is bonded to the CNTs. The coating material can be applied as described below. In some instances, the coating contains one or more oligomeric materials, polymeric materials, waxes, or combinations thereof. In other instances, the coating contains one or more non-polymeric materials. In some instances, the coating can contain a mixture of oligomeric, waxes, and/or polymeric material and non-polymeric materials.

In certain instances, the coating material(s) act as a bonding agent(s) which can bonded, such as chemically, the carbon nanotubes of the stacked arrays or sheets. Without limitation, such coating material(s) which can act as bonding agents(s) can be selected from adhesives (i.e., acrylate adhesives) and a phase change material (i.e., a wax or waxes).

In some instances, the coating which adheres or is bonded to the CNTs of an array is applied before two or more CNT arrays or sheets are stacked while in other instances, the coating which adheres or is bonded to the CNTs of an array is applied following stacking of two or more CNT arrays or sheets. In yet other instances, the coating is infiltrated or backfilled into multilayered or multitiered structures formed of stacked CNT arrays or sheets and adheres or is bonded to the CNTs of the arrays forming the structure. As used herein, “infiltration” or “infiltrated” refer to a coating material(s) which are permeated through at least some of the carbon nanotubes of the arrays or sheets which were stacked to form the multilayered or multitiered structures. In some instances, the extent of infiltration is in the range of 0.1-99.9%. In some instances, the infiltrated coating material at least partially fills the interstitial space between carbon nanotubes while in some other instances the infiltrated coating coats at least some of the surfaces of the carbon nanotubes, or both. In some instances, the infiltrated coating material fills the all or substantially all (i.e., at least about 95%, 96%, 97%, 98%, or 99%) of the interstitial space between carbon nanotubes present in the tiers or layers of the structure formed by stacking of the CNT arrays or sheets.

A variety of materials can be coated onto the CNT arrays or sheets, prior to stacking, during stacking, or following stacking. In particular instances, the coatings can cause a decrease in the thermal resistance of the CNTs of arrays or sheets of structure having a plurality of layers or tiers, as defined herein. The coatings can be applied conformally to coat the tips and/or sidewalls of the CNTs. It is also desirable that the coating be reflowable as the interface is assembled using, for example, solvent, heat or some other easy to apply source. Polymers used as coatings must be thermally stable up to at least 130° C. In some instances, the coating is readily removable, such as by heat or dissolution in a solvent, to allow for “reworking” of the interface. “Reworking”, as used herein, refers to breaking the interface (i.e., removing the coating) by applying solvent or heat.

i. Polymeric Coating Materials

In some instances, the coating material is, or contains, one or more polymer or polymeric materials. The polymer coating can contain a conjugated polymer, such as an aromatic, heteroaromatic, or non-aromatic polymer, or a non-conjugated polymer.

Suitable classes of conjugated polymers include polyaromatic and polyheteroaromatics including, but not limited to, polythiophenes (including alkyl-substituted polythiophenes), polystyrenes, polypyrroles, polyacetylenes, polyanilines, polyfluorenes, polyphenylenes, polypyrenes, polyazulenes, polynaphthalenes, polycarbazoles, polyindoles, polyazepines, poly(3,4-ethylenedioxythiophenes), poly(p-phenyl sulfides), and poly(p-phenylene vinylene). Suitable non-aromatic, conjugated polymers include, but are not limited to, polyacetylenes and polydiacetylenes. The polymer classes listed above include substituted polymers, wherein the polymer backbone is substituted with one or more functional groups, such as alkyl groups. In some instances, the polymer is polystyrene (PS). In other instances, the polymer is poly(3-hexythiophene) (P3HT). In other instances, the polymer is poly(3,4-3thylenedioxythiophene) (PEDOT) or poly(3,4-3thylenedioxythiophene) poly(styrenesulfonate) (PEDOT:PSS).

In other instances, the polymer is a non-conjugated polymer. Suitable non-conjugated include, but are not limited to, polyvinyl alcohols (PVA), poly(methyl methacrylates) (PMMA), polydimethylsiloxanes (PDMS), polyurethane, silicones, acrylics, and combinations (blends) thereof.

In other instances, the polymer is a paraffin wax. In other instances, the polymer is a synthetic wax such as Fischer-Tropsch waxes or polyethylene waxes. In other instances the polymer is a silicone wax or alkyl modified silicon wax. In other instances, the polymer is a wax that has a melting temperature above 80, 90, 100, 110, or 120° C., or above 130° C.

In other instances, the polymer is an adhesive, such as, but not limited to, a hot glue or hot melt adhesive that combines wax, tackifiers and a polymer base to provide improved adhesion properties to one or more surfaces. In some instances, the adhesive is a pressure sensitive adhesive. In certain other instances, the adhesive is a monomer that polymerizes upon contact with air or water such as a cyanoacrylate. In yet other instances, the adhesive is a combination of a pressure sensitive adhesive and a thermally activated (or activatable) adhesive polymers which enhances ease of adhesion of a multilayered or multitiered structure described herein which includes such a combination of coatings to a surface(s), by way of the pressure sensitive adhesive and additional and more permanent or semi-permanent adhesion by way of the thermal adhesive.

### 2. Other Coating Materials

i. Metallic Nanoparticles

The CNT arrays or sheets can additionally or alternatively be coated with one or more metal nanoparticles. One or more metal nanoparticles may be adsorbed to the distal ends and/or sidewalls of the CNTs to bond the distal ends and/or sidewalls of the CNTs to a surface, reduce thermal resistance between the CNT array or sheet and a surface, or combinations thereof. Metal nanoparticles can be applied to CNT arrays or sheets using a variety of methods known in the art.

Examples of suitable metal nanoparticles include palladium, gold, silver, titanium, iron, nickel, copper, and combinations thereof.

ii. Flowable or Phase Change Materials

In certain instances, flowable or phase change materials can be applied to the CNT arrays or sheets prior to stacking, during stacking, or following stacking. Flowable or phase change materials may be added to the CNT array or sheet to displace the air between CNTs and improve contact between the distal ends and/or sidewalls of CNTs and a surface, and as a result reduce thermal resistance of the array or sheet and the contact between the array or sheet and a surface, or combinations thereof. Flowable or phase change materials can be applied to CNT arrays using a variety of methods known in the art.

Examples of suitable flowable or phase change materials include paraffin waxes, polyethylene waxes, hydrocarbon-based waxes in general, and blends thereof. Other examples of suitable flowable or phase change materials that are neither wax nor polymeric include liquid metals, oils, organic-inorganic and inorganic-inorganic eutectics, and blends thereof. In some instances, the coating material, such as a non-polymeric coating material and the flowable or phase change material are the same material or materials.

c. Multilayered or Multitiered Carbon Nanotube Structures

The CNT arrays or sheets described above can be stacked according to the methods described below to afford multilayered or multitiered structures. Such multilayered or multitiered structures can be formed or bonded to a substrate surface and a heat dissipation structure can be deposited or bonded onto an opposite surface of the substrate.

For such multilayered or multitiered structures, a layer or tier is formed by contacting/stacking the carbon nanotubes of two CNT arrays or sheets, which interdigitate at least partially, and which may optionally be coated with a suitable coating material as described herein. It is understood that for multilayered or multitiered structures, there is at least one exposed surface onto which a heat dissipation structure can be formed/deposited or bonded directly thereto.

In some instances, the multilayered or multitiered structures can further include a coating, a coating of metallic nanoparticles, and/or a coating of flowable or phase change materials on the nanostructure elements, such as CNTs, of the arrays.

At least two CNT arrays or sheets can be stacked to form the multilayered or multitiered structures. By using more CNT arrays the thickness of the multilayered or multitiered structures can be increased as needed. In some instances, up to 5, 10, 15, 20, 25, 30, or more CNT arrays or sheets can be stacked according to the method described above. The thickness of the resulting multilayered or multitiered structures formed by stacking can be in the range 1-10,000 microns or more. In some instances, the thickness of the resulting multilayered or multitiered structures formed by stacking can be 1-3,000 micrometers or 70-3,000 micrometers. In some instances, the number of layers and/or thickness is based on the thickness of the CNT forest formed on the arrays used in the stacking process.

In a non-limiting instance, at least two vertically aligned arrays or sheets formed on supports/substrates are stacked/contacted such that the nanostructure elements, such as CNTs, of the arrays at least partially interdigitate on contact. In one embodiment full interdigitation of nanostructure elements of the arrays occurs within one another when stacked. In other instances, the arrays may interdigitate only at the tips of the nanostructure elements, such as CNTs. In yet other instances, the individual nanostructures can navigate through the nanostructures of the adjacent array during the interdigitating process and the nanostructure elements of the individual arrays, such as the CNTs or some portion thereof, fully or substantially interdigitate within one another; “substantially,” as used herein, refers to at least 95%, 96%, 97%, 98%, or 99% interdigitation between the nanostructure elements of the individual arrays. In some instances, the extent of interdigitation is in the range of about 0.1% to 99% or at least about 1%, 5%, 10%, 20%, 30%, 40%, 50%, 60%, 70%, 80%, 90%, or 95%.

In some instances, the nanostructures of the stacked arrays, which interdigitate at least partially, may also form into larger superstructures, such as, but not limited to, tube bundles, clumps, or rows. These superstructures may be formed through mechanisms such as capillary clumping or by way of application of a polymer coating prior to, during, or following the stacking process.

In some instances, a polymer coating and/or adhesive, or other coating as described above, is applied to the CNT array(s) which are subsequently stacked. In such instances, the thickness of the coating and/or adhesive, or other coating as described above, is about 500-10000 nm, 1-1000 nm, 1-500 nm, or 1-100 nm.

In addition to the above, the favorable deformation mechanics of CNTs present in the multilayered or multitiered structures allow them to efficiently conform to the asperities of adjoining or mating surfaces, resulting in high contact areas when contacted to such surfaces.

### C. Heat Dissipation Structures

Without limitation, various types of heat dissipation structures can be formed or bonded directly onto a surface of a substrate of the devices described herein. In some instances, the heat dissipation structure is selected from a heat sink, a cold plate, a lid, a heat spreader, a water block, a radiator, and a gap filler, and combinations thereof.

The person of ordinary skill in the art is able to manufacture, form, or deposit such heat dissipation structures, such as by additive manufacturing process(es) known in the art directly onto a substrate surface. In one instance, a Selective Laser Sintering (SLS) thermal process can be used to form the heat dissipation structure directly on the surface. Other techniques can also be used, such as wire arc additive manufacturing, laser powder bed fusion, powder direct energy deposition, material jetting, binder jetting, lamination, material extrusion, or vat polymerization.

Alternatively, such heat dissipation structures can be obtained or formed separately and then bonded directly onto a substrate surface. Non-limiting bonding processes can include welding, soldering, sintering, fusion bonding, diffusion bonding, direct bonding, hybrid bonding, and combinations thereof.

It is understood that the heat dissipation structure can be formed of a single type of material or from a combination of materials. In other words, in some instances, the heat dissipation structure can include, for example, a combination of different types of heat dissipation structures which may form a single structure when formed or bonded to the surface of a substrate. In some cases, the heat dissipation structure may include multiple layers of heat dissipation structures therein.

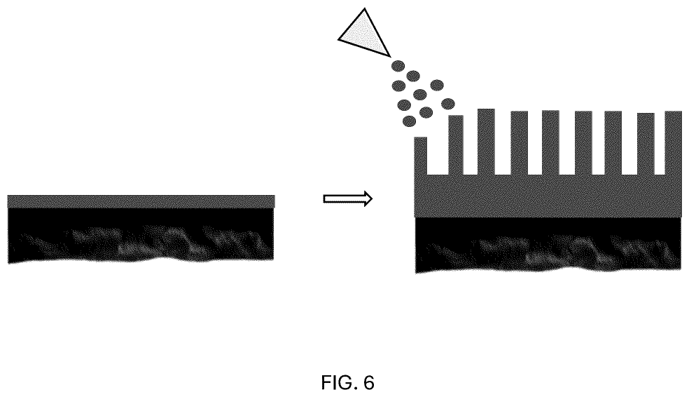

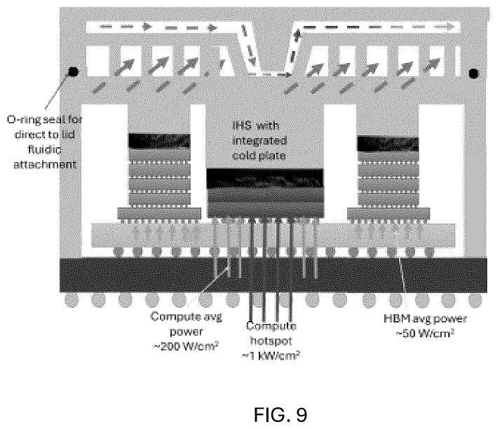

In some instances, the heat dissipation structure includes a surface, which may be planar, which can be coupled to a cold plate structure. Such cold plate structures are known in the art. In other instances, the heat dissipation structure includes a cold plate structure integrated directly thereon, where the cold plate structure can be formed, such as by additive manufacturing, directly onto the heat dissipation structure. See, for example, FIGS. 2D and 6. The cold plate structure may include features such as fins, wicks, or spreaders thereon. In some instances, the cold plate structure fluidic routing channels and is capable of dissipating hotspots up to 10 W/mm². In some instances, the cold plate structure is a fluid-to-fluid spot-to-spot spreader capable of dissipating hotspots up to 10 W/mm² . See, for example, FIG. 9. In some instances, the cold plate structure is capable of dissipating hotspots up to 10 W/mm² .

In some instances, the heat dissipation structures described include cold plate structures that include integrated vapor chambers and heat pipes for addressing hot spots locally on a heat generating device. In some instances, the cold plate structures which may be present in the devices described are made of copper (such as high-purity copper, 99.99% copper).

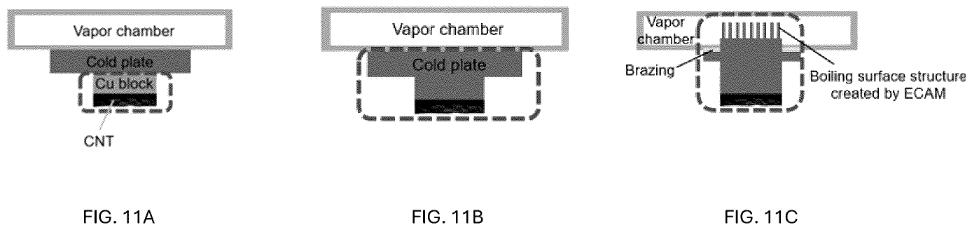

In some instances, the heat dissipation devices include a metal block, such as a copper block, as a heat dissipation structure (see FIG. 11A). In other instances, the heat dissipation devices include a metal block, such as a copper block, as a heat dissipation structure and further include a cold plate structure atop (see FIG. 11B). In yet other instances, the heat dissipation devices include a metal block, such as a copper block, as a heat dissipation structure and further include a cold plate structure atop which includes structures, such as fins, wicks, or spreaders, which can act as boiling surface structures (see FIG. 11C). In the instances, shown in FIGS. 11A-11C, the heat dissipation devices may be interfaced to a vapor chamber, which are art known, and may optionally include brazing at the interface.

In some instances, the heat dissipation structure has an overall thickness in range from between about 250 um up to 5 cm, 250 um up to 4 cm, 250 um up to 3 cm, 250 um up to 2 cm, 250 um up to 1 cm, 250 um up to 0.75 cm, 250 um up to 0.5 cm, 250 um up to 0.25 cm, 250 um up to 0.1 cm, 250 um up to 0.01 cm, or individual values or subranges contained within the aforementioned range.

### III. Methods for Making a Heat Dissipation Device

The heat dissipation devices described herein can be formed according to the methods detailed below.

In one non-limiting example, a method of making a heat dissipation includes the steps of:
(a) forming a thermal interfacial material or a thermal interfacial coating in direct contact onto a first surface of a substrate; and
(b) forming or bonding a heat dissipation structure in direct contact onto a second surface of the substrate;
wherein the first surface and the second surface are on opposing sides of the substrate;
wherein thermal resistance between the substrate, the thermal interfacial material or thermal interfacial coating, and the heat dissipation structure is in a range from between about 0.01 to 0.1 cm² ° C./W, or individual values or sub-ranges contained within the aforementioned range.

In another non-limiting example, a method of making a heat dissipation device includes the steps of:
(a′) providing a substrate comprising a thermal interfacial material or a thermal interfacial coating in direct contact with a first surface of a substrate; and
(b′) forming or bonding a heat dissipation structure in direct contact onto a second surface of the substrate;
wherein the first surface and the second surface are on opposing sides of the substrate;
wherein thermal resistance between the substrate, the thermal interfacial material or thermal interfacial coating, and the heat dissipation structure is in a range from between about 0.01 to 0.1 cm² ° C./W, or individual values or sub-ranges contained within the aforementioned range.

In some instances of the methods above, the first surface includes one or more non-planar features thereon to contact or maximize contact to one or more non-planar surfaces or curvatures present on a heat source; and wherein at least the one or more non-planar features include the thermal interfacial material or thermal interfacial coating thereon. In some other instances of the methods above, the first surface is contoured to contact or maximize contact to one or more non-planar surfaces or curvatures present on a heat source. In some instances, the one or more non-planar surfaces or curvatures on the heat source comprise ovoid, concave, saddle point, and/or stepwise features. In some instances of the methods above, the one or more non-planar surfaces or curvatures on the heat source result from warpage during operation of the heat source and the thermal interfacial material or thermal interfacial coating remains in full contact or substantially in contact with the one or more non-planar surfaces or curvatures on the heat source during operation. “Substantially in contact,” refers to at least about 90%, 91%, 92%, 93%, 94%, 95%, 96%, 97%, 98%, 99%, 99.1%, 99.2%, 99.3%, 99.4%, 99.5%, 99.6%, 99.7%, 99.8%, 99.9%, or more, of the surface area of the one or more non-planar surfaces or curvatures on the heat source are in contact with the thermal interfacial material or thermal interfacial coating of the device.

In yet another non-limiting example, a method of making a heat spreader device includes the steps of:
(a″) determining or predicting, such as by modeling, surface topology and/or curvature of a heat source prior to and during operation of the heat source;
(b″) forming a heat dissipation structure comprising a bottom surface with one or more non-planar surfaces or curvatures, such as by contouring, to match the determined or predicted surface topology and/or curvature of the heat source prior to and/or during operation;
wherein the heat dissipation structure is directly formed on or bonded to a substrate comprising a thermal interfacial material or a thermal interfacial coating; and
wherein thermal resistance between the substrate, the thermal interfacial material or thermal interfacial coating, and the heat dissipation structure is in a range from between about 0.01 to 0.1 cm² ° C./W.

Determining or predicting surface topology and/or curvature of a heat source, such as heat generating device, can be achieved by suitable methods and models. For example, predictions of the median warpage of heat sources, such as advanced packages can be from first principles, considering both the material properties of the various components within the source/package, as well as conditions under which the components were assembled. For example, when multiple dies of different thicknesses are assembled on a substrate, the resulting warped geometry of the package will be dependent on the thickness of the substrate and the dies, the material properties of the substrate and the dies, the standoff height, diameter, and pitch of die-to-substrate interconnects, as well as whether the dies are underfilled. Thus, when multiple dies of different form factors are assembled on a substrate, the resulting heat producing structure may not have a uniform curvature but will create a landscape with different curvatures. To be able to predict such multiply curved sections, models, such as thermo-mechanical models, can take into consideration the assembly process profiles, temperature-, time-, and direction-dependent thermo-physical properties of materials, and the geometry and dimensions of various elements in the packaging configuration. Without limitation, predicted warpage profiles can be validated quantitatively using measurement tools, such as, for example, shadow moire and optical CMM which are known in the art for measuring surface deformations and warpage in microelectronic packages. Validation can be used, at least in part, for iterative refinement of models, but also to establish uncertainty windows for predicted device geometries. Such thermo-mechanical structural models can provide not only as built room-temperature warpage profiles, but also an understanding of how the curvature changes as a function of operating temperature of the heat source/device. Understanding the change in warpage is important because it incorporates a temporal parameter into the geometric uncertainty window.

In some instances, the surface topology and/or curvature of the heat source comprises ovoid, concave, saddle point, and/or stepwise features. In some instances, the surface topology and/or curvature of the heat source result from warpage during operation of the heat source and the thermal interfacial material or thermal interfacial coating remains in full contact or substantially in contact with the surface topology and/or curvature of the heat source during operation.

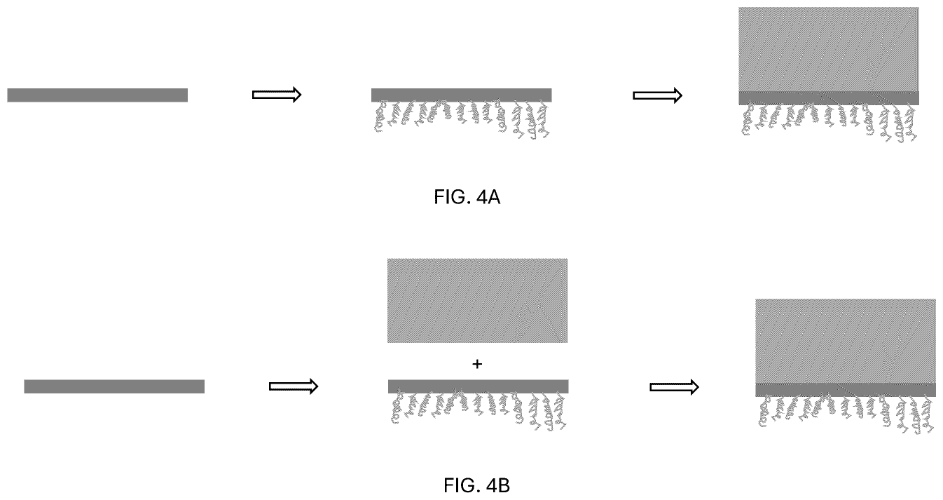

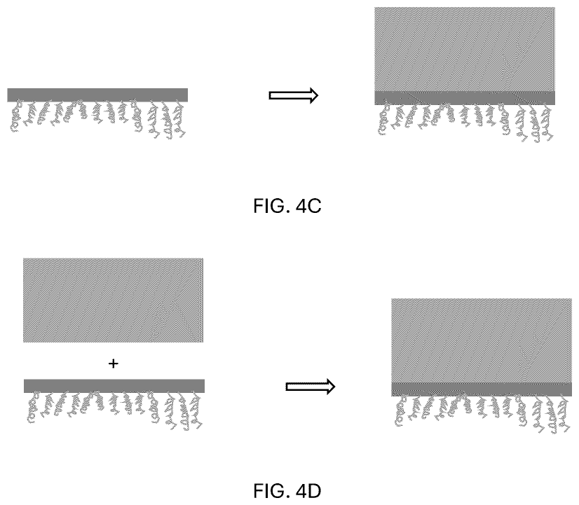

In some instances, the heat dissipation structure comprises a compressible or conformable layer therein that provides local modulus reduction and is able to conform to one or more non-planar surfaces or curvatures present on a heat source when compressed thereon. In some instances, the compressible or conformable layer is formed of or comprises a lattice structure. In some instances, the compressible or conformable layer has a thickness in range from between about 5 um-100 um, or up to about 500 um, 1000 um, 2000 um, or up to 3 mm. In one instance, FIG. 4A shows a non-limiting exemplary method flow whereby a substrate (left) has a thermal interfacial material or a thermal interfacial coating formed on one surface of the substrate (center) and a heat dissipation structure is formed directly on an opposite surface of the substrate (right). In another example, FIG. 4B shows a non-limiting exemplary method flow whereby a substrate (left) has a thermal interfacial material or a thermal interfacial coating formed on one surface of the substrate (center) and a heat dissipation structure (either formed or provided separately as a free standing structure) is bonded directly onto an opposite surface of the substrate (right).

In some other instances, as shown in FIG. 4C, a substrate having a thermal interfacial material or a thermal interfacial coating already formed on a surface of the substrate is provided or obtained instead of manufactured (left) and a heat dissipation structure is formed directly on an opposite surface of the substrate (right). In yet another instance, as shown in FIG. 4D, a substrate having a thermal interfacial material or a thermal interfacial coating already formed on a surface of the substrate is provided or obtained instead of manufactured (left) and a heat dissipation structure (either formed or provided separately as a free standing structure) is bonded directly on an opposite surface of the substrate (right).

In some instances, as shown in FIGS. 1E, 2B, and 2C, the heat dissipation structure can include includes contouring or non-planar features, such as pillars, thereon. Such features can be fabricated using art known techniques, such as additive manufacturing, machining, etching, casting, moulding, and/or stamping.

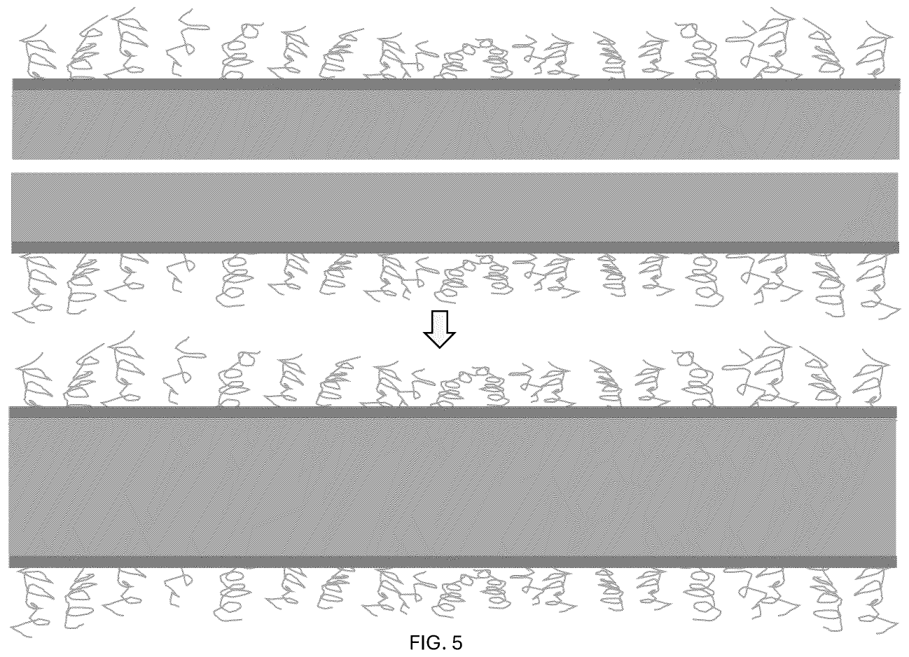

As previously noted, in some instances, a heat dissipation device may include two substrates having thermal interfacial material or thermal interfacial coatings on a surface of each respective substrate and a heat dissipation structure in between contacts the opposing surfaces of the two respective substrates. Such a heat dissipation device can be formed, as shown in the method flow of FIG. 5 which shows that two heat dissipation devices can be bonded directly by bonding their respective heat dissipation structures via a suitable bonding technique (see described bonding techniques below). More complex heat dissipation device shown in FIG. 2B, having pillars, can be formed in a similar manner forming various heat dissipation devices which are bonded together.

The heat dissipation devices formed according to the methods can have any suitable shape or dimensions needed to contact one or more mating surfaces of a heat-generating device (such as a computer chip or component).

In some instances, the heat dissipation structure is formed by an additive manufacturing process, such as a Selective Laser Sintering (SLS) thermal process, wire arc additive manufacturing, laser powder bed fusion, powder direct energy deposition, material jetting, binder jetting, lamination, material extrusion, or vat polymerization. Alternatively, the heat dissipation structure can be bonded directly onto the second surface by a process selected from the group consisting of welding, soldering, sintering, fusion bonding, diffusion bonding, direct bonding, hybrid bonding, and combinations thereof. Typically, the heat dissipation structure whether formed or bonded onto the surface of the substrate forms an interface-free bond with the second surface.

In some instances, the heat dissipation device is formed on a pre-form or build plate which imparts a desired shape or form (i.e., curvature) to the heat dissipation formed onto the TIM substrate such that the as-made heat dissipation structure matches the shape or form of a mating surface of a heat generating/source device. Thus, a pre-form or build plate can be used which has the shape or form (i.e., curvature) of a mating surface of a heat generating/source device. Thus, the resulting heat dissipation device can be tailored and easily mated onto the mating surface of the heat generating/source device. Thus, in some instances of the methods, the substrate including the thermal interfacial material or the thermal interfacial coating thereon is placed onto a pre-form or build plate prior to step (b) or (b′).

In certain instances, the methods include a thermal control process that prevents or reduces any damage to the thermal interfacial material or the thermal interfacial coating during step (b) or (b′). This can be achieved, for example, by use of a cold plate or other thermal control device at the build surface, or through control of the energy deposition rate of the heat dissipation structure in order to avoid or reduce damage or destruction of the thermal interfacial material or the thermal interfacial coating on the substrate. It may alternately be achieved through use of energy storage through latent heat in or near the thermal interface layer, or through for example thermal decomposition of a sacrificial coating layer which is included in order to prevent or reduce damage or destruction of the thermal interfacial material or the thermal interfacial coating on the substrate.

The thermal interfacial material or a thermal interfacial coating is present on a surface of a substrate (i.e., metallic foil, such as made of aluminum or copper), as described below. In some instances, the substrate has a thickness in range from between about 10 um to 6 mm, 50-500 um, 100-1000 um, or 100 to 5,000 um; or an individual thickness or subrange contained within the aforementioned ranges.

In some instances, the thermal interfacial material or a thermal interfacial coating is or includes a carbon nanotube array or sheet and can be formed from a single tiered or single layered structure or can be from multitiered or multilayered structures, as detailed below. In some instances, the thermal interfacial material or thermal interfacial coating has a thickness in range from between about 5 um-100 um, or up to about 500 um, 1000 um, 2000 um, and sometimes up to 3 mm; or an individual thickness or subrange contained within the aforementioned ranges.

The devices formed by the methods described above may, in some instances, be evaluated or validated for performance and reliability on packages representing the major advanced packaging strategies: fan out, 2.5D and 3D HI. Such thermal and mechanical characterizations can be executed on thermal test vehicles (TTVs) built to represent the geometry, mechanics, and thermal profiles of advanced packaging nodes. For example, a TTV platform amenable to representing the geometry (scalable to any desired package size), mechanics (flexible in substrate and PCB material selection) and power maps (up to 256 discrete hotspot “pixels”) of a device for testing can be used. All the TTV circuitry required to perform measurements and temperature estimations can be included on one PCB, enabling rapid validation with high mechanical fidelity. In parallel, utility silicon chiplets with in situ temperature sensing and heating elements, with a target power density of >4 W/mm² can also be used for evaluation/validation. Non-uniform power distribution across a chiplet can be achieved through the control of the circuitry, and the chiplet may include a redistribution layer and through silicon vias for stacking. Chiplets can be packaged in various substrate/interposer/fan-out configurations for interconnection with the circuitry. For example, a heat dissipation device can be assembled to a TTV die and validation of the effectiveness of the topologically matched structures through contact area and contact pressure mapping using, for example, C-SAM, as well as Tekscan force, and pressure mapping tools can be performed. Validation of not just as designed contact, but also how contact varies as a function of temperature and through thermal cycling can also be evaluated. Evaluation of reliability and thermal performance through continuous 100-hour operation at, for instance, 85° C., as well as through power cycling at various cycle intervals, such as 1,000 cycle intervals, can be performed. Thermal performance of each heat dissipation device can be tracked via on chip or on-board temperature detectors, with no external instrumentation required. After testing, select heat dissipation devices can be cross-sectioned to evaluate changes in contact due to delamination cracking or other failure modes. Moving beyond TTVs, such devices can also be attached to a functional bare die server to demonstrate performance in a relevant environment. In some instances, after testing a heat dissipation device can be cross-sectioned to evaluate changes in contact due to delamination cracking or other failure modes. In some instances, a heat dissipation device described herein exhibits no or substantially no delamination cracking after continuous 100-hour operation at, for instance, 85° C., as well as through repeated power cycling, such as 1,000 cycle intervals. “Substantially no delamination or cracking” refers to less than about 10%, 9%, 8%, 7%, 6%, 5%, 4%, 3%, 2%, 1%, 0.5%, 0.1%, or less of the contact area at the interface between the heat dissipation device and a die exhibiting evidence of delamination cracking.

### 1. Carbon Nanotube Arrays and Carbon Nanotube Sheets

Carbon nanotube arrays can be prepared using techniques well known in the art. In one instance, the arrays are prepared as described in U.S. Publication No. 2014-0015158-A1, incorporated herein by reference.

Carbon nanotube sheets can be prepared using techniques well known in the art. In one instance, the sheets are prepared as described in U.S. Pat. No. 7,993,620 B2, incorporated herein by reference. In this instance, CNT agglomerates are collected into sheets in-situ inside the growth chamber on metal foil substrates.

a. Polymer Coatings

Polymers to be coated onto the CNTs of the array or sheet can be dissolved in one or more solvents and spray or dip coated or chemically or electrochemically deposited onto the vertical CNT forests or arrays grown on a substrate, or on a sheet, as described above. The coating materials can also be spray coated in powder form onto the top of vertical CNT forests or arrays grown on a substrate, or on CNT sheets as described above. The coatings include polymers or molecules that bond to CNTs through van der Waals bonds, π-π stacking, mechanical wrapping and/or covalent bonds and bond to metal, metal oxide, or semiconductor material surfaces through van der Waals bonds, π-π stacking, and/or covalent bonds.

For spray or dip coating, coating solutions can be prepared by sonicating or stirring the coating materials for a suitable amount of time in an appropriate solvent. The solvent is typically an organic solvent or solvent and should be a solvent that is easily removed, for example by evaporation at room temperature or elevated temperature. Suitable solvents include, but are not limited to, chloroform, xylenes, hexanes, pyridine, tetrahydrofuran, ethyl acetate, and combinations thereof. The polymer can also be spray coated in dry form using powders with micron scale particle sizes, i.e., particles with diameters less than about 100, 50, 40, 20, 10 micrometers. In this instance, the polymer powder would need to be soaked with solvent or heated into a liquid melt to spread the powder particles into a more continuous coating after they are spray deposited.

The thickness of the polymer coatings is generally between 1 and 1000 nm, between 1 and 500 nm, between 1 and 100 nm, or between 1 and 50 nm. In some instances, the coating thickness is less than 500, 450, 400, 350, 300, 250, 200, 150, 100, 90, 80, 70, 60, 50, 40, 30, 20 or 10 nm.

Spray coating process restricts the deposition of coating to the CNT tips and limits clumping due to capillary forces associated with the drying of the solvent. The amount of coating visible on the CNT arrays increases with the number of sprays. Alternative techniques can be used to spray coat the coating materials onto the CNT arrays including techniques more suitable for coating on a commercial scale.

In another instance that demonstrates a coating process, CNT sheets can be dipped into coating solutions or melted coatings to coat CNTs throughout the thickness of the sheets, increasing the thermal conductivity of the sheet in the cross-plane direction by greater than 20, 30, 50, or 70%.

In other instances, the coating material can be deposited on the CNT array or sheet using deposition techniques known in the art, such as chemical deposition (e.g., chemical vapor deposition (CVD)), aerosol spray deposition, and electrochemical deposition.

In one instance, a polymer coating can be applied by electrochemical deposition. In electrochemical deposition, the monomer of the polymer is dissolved in electrolyte and the CNT array or sheet is used as the working electrode, which is opposite the counter electrode. A potential is applied between the working and counter electrode with respect to a third reference electrode. The monomer is electrooxidized on the CNT array tips or sheet sidewalls that face the electrolyte as a result of the applied potential. Controlling the total time in which the potential is applied controls the thickness of the deposited polymer layer.

In some instances, the polymer coating material is, or contains, one or more oligomeric and/or polymeric materials. In particular instances, the polymer can be a conjugated polymer, including aromatic and non-aromatic conjugated polymers. Suitable classes of conjugated polymers include polyaromatic and polyheteroaromatics including, but not limited to, polythiophenes (including alkyl-substituted polythiophenes), polystyrenes, polypyrroles, polyacetylenes, polyanilines, polyfluorenes, polyphenylenes, polypyrenes, polyazulenes, polynaphthalenes, polycarbazoles, polyindoles, polyazepines, poly(3,4-ethylenedioxythiophenes), poly(p-phenyl sulfides), and poly(p-phenylene vinylene). Suitable non-aromatic polymers include, but are not limited to, polyacetylenes and polydiacetylenes. The polymer classes listed above include substituted polymers, wherein the polymer backbone is substituted with one or more functional groups, such as alkyl groups. In some instances, the polymer is polystyrene (PS). In other instances, the polymer is poly(3-hexythiophene) (P3HT).

In other instances, the polymer is a non-conjugated polymer. Suitable non-conjugated include, but are not limited to, polyvinyl alcohols (PVA), poly(methyl methacrylates) (PMMA), polysiloxanes, polyurethanes, polydimethylsiloxanes (PDMS), and combinations (blends) thereof.

In other instances, the polymer is a paraffin wax. In other instances, the polymer is a synthetic wax such as Fischer-Tropsch waxes or polyethylene waxes. In other instances the polymer is a silicone wax or alkyl modified silicon wax. In other instances, the polymer is a wax that has a melting temperature above 80, 90, 100, 110, and 120° C., or above 130° C.

In some other instances, the polymer is an adhesive, such as, but not limited to, a hot glue or hot melt adhesive that combines wax, tackifiers and a polymer base to provide improved surface adhesion. In some instances, the adhesive is a pressure sensitive adhesive. In certain other instances the adhesive is a monomer that polymerizes upon contact with air or water such as a cyanoacrylate. In yet other instances, the adhesive is a combination of a pressure sensitive adhesive polymer and a thermally activated (or activatable) adhesive polymer which enhances ease of adhesion of a multilayered or multitiered structure described herein which includes such a combination of coatings to a surface(s), by way of the pressure sensitive adhesive and additional and more permanent or semi-permanent adhesion by way of the thermal adhesive.

b. Metallic Nanoparticles

The CNT arrays or sheets can be coated with one or more metal nanoparticles. One or more metal nanoparticles may be adsorbed to the distal ends and/or sidewalls of the CNTs to bond the distal ends of the CNTs to a surface, reduce thermal resistance between the CNT array or sheet and a surface, or combinations thereof. Metal nanoparticles can be applied to CNT arrays or sheets using a variety of methods known in the art. For example, a solution of metal thiolate such as palladium hexadecanethiolate can be sprayed or spin coated onto the distal ends and/or sidewalls of the CNTs, and the organics can be baked off to leave palladium nanoparticles. In another example, electron-beam or sputter deposition can be used to coat metal nanoparticles or connected “film-like” assemblies of nanoparticles onto the distal ends and/or sidewalls of the CNTs. The metallic particles can be coated simultaneously with the coating or before or after coating.

Examples of suitable metal nanoparticles include palladium, gold, silver, titanium, iron, nickel, copper, and combinations thereof.

c. Flowable or Phase Change Materials

In certain instances, flowable or phase change materials can be applied to the CNT array or sheet. Flowable or phase change materials may be added to the CNT array or sheet to displace the air between CNTs and improve contact between the distal ends of CNTs and a surface, and as a result reduce thermal resistance of the array or sheet and the contact between the array or sheet and a surface, or combinations thereof. Flowable or phase change materials can be applied to CNT arrays or sheets using a variety of methods known in the art. For example, flowable or phase change materials in their liquid state can be wicked into a CNT array or sheet by placing the array or sheet in partial or full contact with the liquid.

Examples of suitable flowable or phase change materials include paraffin waxes, polyethylene waxes, hydrocarbon-based waxes in general, and blends thereof. Other examples of suitable flowable or phase change materials that are neither wax nor polymeric include liquid metals, oils, organic-inorganic and inorganic-inorganic eutectics, and blends thereof. In some instances, the coating material(s) and the flowable or phase change material are the same.

The coatings, metallic particles, and/or flow or phase change materials described above can be applied directly to the CNT arrays or sheets and the coated CNT arrays or sheets can subsequently be stacked to form multilayered or multitiered structures. In certain other instances, the coatings, metallic particles, and/or flow or phase change materials described above are applied during the stacking of two or more CNT arrays or sheets. In still other instances, the coatings, metallic particles, and/or flow or phase change materials described above are applied following the stacking of two or more CNT arrays or sheets. In non-limiting instances, multilayered or multitiered structure(s) are formed by first stacking two or more CNT arrays or sheets and then the at least partially interdigitated tiers of the formed structures are infiltrated with one or more coatings, metallic particles, and/or flow or phase change materials, or combinations thereof. The introduction of such coatings/materials into the at least partially interdigitated tiers of the multilayered or multitiered structure(s) prior to, during, or after stacking can be used to modify and/or enhance the thermal transport or thermal resistance properties of the multilayered or multitiered structures resulting from the stacking of the CNT arrays or sheets.

### 2. Multilayered or Multitiered Structures

In some instances described herein, the multilayered or multitiered structures formed by stacking of CNT arrays or sheets are formed by a method including the steps of:
(1) providing at least two or more CNT arrays or sheets; and
(2) stacking the at least CNT arrays or sheets
wherein the stacking results in at least partial interdigitation of the nanostructures, CNTs, of the arrays or sheets.

It is understood that for such multilayered or multitiered structures, there is at least one exposed surface onto which a heat dissipation structure can be formed/deposited or bonded directly thereto.

In some instances, the method of making the multilayered or multitiered structures further includes a step of applying or infiltrating a coating, a coating of metallic nanoparticles, and/or a coating of flowable or phase change materials, which are described above. In some instances, the step of applying or infiltrating a coating, a coating of metallic nanoparticles, and/or a coating of flowable or phase change materials occurs prior to stacking, alternatively during stacking, or alternatively after stacking. In yet other instances, the method includes applying pressure during the stacking step. The applied pressure may be in the range of about 1-100 psi, 1-50 psi, 1-30 psi, 1-20 psi, or about 1-15 psi. In some instances, the pressure is about 15 psi. Pressure may be applied continuously until the adjacent tiers are bonded, if a coating material(s) which can act as a bonding agent, such as an adhesive or phase change material, is used. Pressure may be applied for any suitable amount of time. In some instances, only a short time is used, such as less than 1 minute, if no bonding agent is used.

At least two CNT arrays or sheets can be stacked to form the multilayered or multitiered structures. By using more CNT arrays the thickness of the multilayered or multitiered structures can be increased as needed. In some instances, up to 5, 10, 15, 20, 25, 30, or more CNT arrays or sheets can be stacked according to the method described above. The thickness of the resulting multilayered or multitiered structures formed by stacking can be in the range 1-10,000 microns or more.

In a non-limiting instance, at least two vertically aligned arrays or sheets formed on supports/substrates are stacked/contacted such that the nanostructure elements, such as CNTs, of the arrays at least partially interdigitate on contact. In one instance, full interdigitation of nanostructure elements of the arrays occurs within one another when stacked. In other instances, the arrays may interdigitate only at the tips of the nanostructure elements, such as CNTs. In yet other instances, the individual nanostructures can navigate through the nanostructures of the adjacent array during the interdigitating process.

In some instances the nanostructures of the stacked arrays, which interdigitate at least partially, may also form into larger superstructures, such as, but not limited to, tube bundles, clumps, or rows. These superstructures may be formed through mechanisms such as capillary clumping or by way of application of a polymer coating prior to, during, or following the stacking process.

In some instances, a polymer coating and/or adhesive, or other coating as described above, is applied to the CNT array(s) which are then stacked. In such instances, the thickness of the coating and/or adhesive, or other coating as described above, is about 1-1000 nm, 1-500 nm, or 1-100 nm.

In certain instances of the above method, following the stacking step the method further includes a step of applying an adhesive, such as but not limited to a hot glue or hot melt adhesive that combines wax, tackifiers and a polymer base to the resulting stack to provide improved adhesion properties to one or more surfaces of the stacked/tiered CNT arrays forming the multilayered or multitiered structure. In some instances, the adhesive is a pressure sensitive adhesive. In yet other instances, the adhesive is a combination of a pressure sensitive adhesive polymer and a thermally activated (or activatable) adhesive polymer which enhances ease of adhesion of a multilayered or multitiered structure described herein which includes such a combination of coatings to a surface(s), by way of the pressure sensitive adhesive and additional and more permanent or semi-permanent adhesion by way of the thermal adhesive.

### 3. Heat Dissipation Structures

Various types of heat dissipation structures can be formed or bonded directly onto a surface of a substrate of the devices in the above methods. In some instances, the heat dissipation structure is selected from a heat sink, a cold plate, a lid, a heat spreader, a water block, a radiator, and a gap filler, and combinations thereof.

The person of ordinary skill in the art is able to manufacture, form, or deposit such heat dissipation structures, such as by additive manufacturing process(es) known in the art directly onto a substrate surface. In one instance, a Selective Laser Sintering (SLS) thermal process can be used to form the heat dissipation structure directly on the surface. Other techniques can also be used, such as wire arc additive manufacturing, laser powder bed fusion, powder direct energy deposition, material jetting, binder jetting, lamination, material extrusion, or vat polymerization.

Alternatively, such heat dissipation structures can be obtained or formed separately and then bonded directly onto a substrate surface. Non-limiting bonding processes can include welding, soldering, sintering, fusion bonding, diffusion bonding, direct bonding, hybrid bonding, and combinations thereof.

It is understood that the heat dissipation structure can be formed of a single type of material or from a combination of materials. In other words, in some instances, the heat dissipation structure can include, for example, a combination of different types of heat dissipation structures which may form a single structure when formed or bonded to the surface of a substrate. In some cases, the heat dissipation structure may include multiple layers of heat dissipation structures therein.

In some instances, the heat dissipation structure has an overall thickness in range from between about 250 um up to 5 cm, or individual values or subranges contained within the aforementioned range.

The heat dissipation structure may be made of any suitable material. Typically, the heat dissipation structure is made of the same material as the substrate which has the thermal interfacial material or thermal interfacial coating thereon. In some instances, the heat dissipation structure formed or bonded to the substrate is made of copper, such as high-purity copper (99.9% copper).

### IV. Heat Dissipation Device Applications

The heat dissipation devices described herein are suited for applications where the heat dissipation devices are contacted to heat-generating devices or heat sources. In one non-limiting instance, a method of dissipating heat includes the steps of:
(i) contacting a heat dissipation device, such as those described herein, to a heat source;
wherein the heat dissipation device increases dissipation of heat generated by the heat source by at least about 10%. In some instances, the heat dissipation device increases dissipation of heat generated by the heat source by at least about 20%, 30% 40%, 50%, 60%, 70%, 80%, 90%, or greater.

In some instances, the heat source includes one or more non-planar surfaces or curvatures; and the thermal interfacial material or thermal interfacial coating of the heat dissipation device remains in full contact or substantially in contact with the one or more non-planar surfaces or curvatures on the heat source during operation. In some other instances, the heat source comprises one or more non-planar surfaces or curvatures; and wherein the device comprises a contoured surface to contact or maximize contact to the one or more non-planar surfaces or curvatures of the heat source. In some instances, the one or more non-planar surfaces or curvatures on the heat source comprise ovoid, concave, saddle point, and/or stepwise features. In some instances, the one or more non-planar surfaces or curvatures on the heat source result from warpage during operation of the heat source and the thermal interfacial material or thermal interfacial coating remains in full contact or substantially in contact with the one or more non-planar surfaces or curvatures on the heat source during operation.

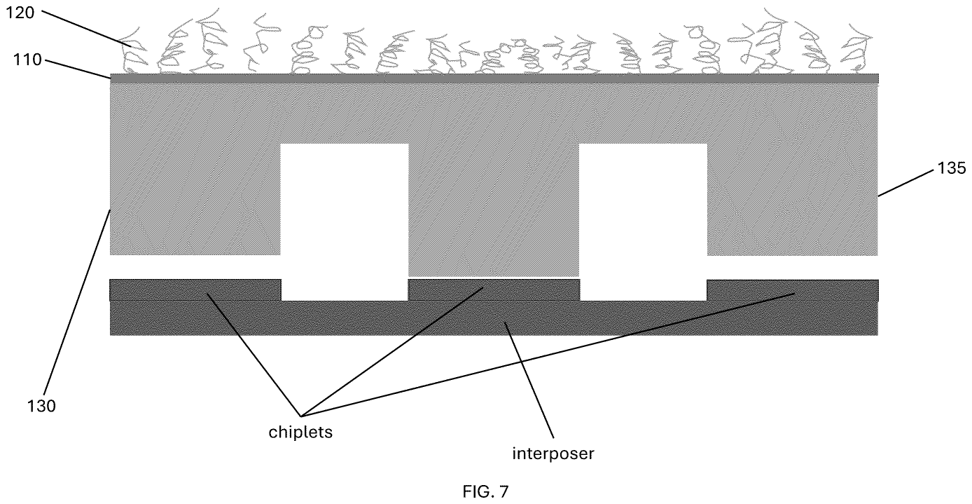

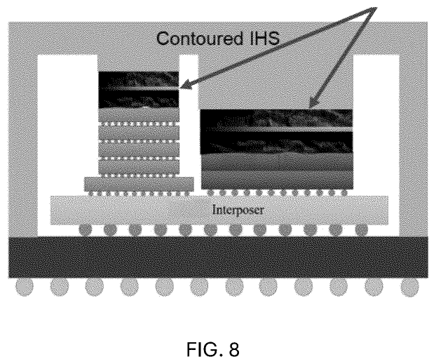

As an example, FIGS. 7 and 8 show non-limiting cross-sectional views of heat dissipation devices according to an embodiment described that includes contouring or non-planar features, such as pillars, which are contacted to a heat-generating device or source formed of chiplets on an interposer.

In some instances, the heat source is selected from the group consisting of a microchip, microprocessors (CPU), graphics processing unit (GPU), power transistors, light-emitting diodes, battery packs, power supplies, power converters, radio frequency amplifiers, electric motors, electronic inverters, laser diodes, and optoelectronic devices.

### Prophetic Example 1

### Background

Advanced packaging is driving widespread nonplanarity in modern and next generation systems that makes ensuring reliable, low resistance connection to external heat sinks a daunting task. 2.5D package surfaces may be ovoid, concave, saddle, or other related shapes, and 3D systems introduce stepwise topology into these already complex surfaces. This diversity of system designs makes determining thermal requirements a tedious cycle of trial and error. System level parameters, like total design power, are relatively straightforward to define, and local parameters, like power density and hot spot location, can be reasonably approximated from the system architecture. However, the path from die level heat generation to its ultimate dissipation at the cold plate level is more difficult to quantify or design with precision due to the peculiarities of the nonplanar, multiple interface path from junction to ambient.

To enable scale, and ultimately ensure that systems can be used with the confidence that the full as-designed, unthrottled, capabilities will be useable, a more modular approach to package design must be made available. A key driver of the difficulty in truly realizing systems that can operate without significant thermal bottlenecks is the complex, multi-party interactions that must occur to produce functioning hardware in the field. Semiconductor packages often move through a process starting with design and development typically at a fabless manufacturer, followed by production at a foundry or outsourced semiconductor assembly and test (OSAT) facility elsewhere. Those semi packages then get integrated into larger systems by a diverse network of third-party Original Design or Original Equipment Manufacturers (ODMs or OEMs) who are not necessarily closely tied into the upstream engineering that has occurred to produce those components. Each player in this complex ecosystem has different business drivers and willingness to absorb risk which necessitates that a diverse set of system solutions, like heat sinks and cold plates, will always exist and require package level standardization to minimize/reduce integration risk.

As package warpage becomes an ever-increasing concern, due to package sizes, 2.5D and heterogenous integration, and multi-chiplet systems (among other things), the reliance on multi-party empiricism to determine requirements will become increasingly intractable and inefficient. Instead, an approach that creates an integrated heat spreader (IHS) is proposed that drives the bond line thickness of interfaces within the stack to as thin as possible by contouring the surface of integrated heat spreaders to the as-packaged warpage (or other geometric nonplanarity) of the device. Such HIS can be designed by several approaches, from building die specific profiles into the IHS, to contouring the IHS to minimize the bond line specifically in the vicinity of high power chiplets, to locally modifying the modulus of the IHS to enable the die facing side of the lid to conform to the die. As a final step, the entire HIS structure can be built directly on to a metal substrate-supported, aligned carbon nanotube matrix, producing an IHS structure with a built in, ultra-thin thermal interface that will still be able to contact a package of any warpage level, and move with elasticity through a large enough range to accommodate dynamic changes in warpage even in operation. On the cold plate side, the IHS structure will also be able to deliver a consistent, smooth, and flat interface that can be mated to any OEM or ODM heat sink with full performance expectations every time.

Beyond addressing a pressing thermal challenge, this approach will also eliminate the mounting risk of die cracking that is seen even today, especially in areas like perimeter high bandwidth memory (HBM) in bare die systems (R. Agarwal et al., “3D Packaging Challenges for High-End Applications,” 2017 IEEE 67th Electronic Components and Technology Conference (ECTC), Orlando, FL, USA, 2017, pp. 1249-1256). As packages get larger, and more and more complex, the stress concentrations that can arise in non-planar systems in direct contact with metal cold plates will become more of a concern in bare die systems. The movement towards bare die in the most recent generation of devices has been driven by a desire to minimize overall interface impact by reducing the number of interfaces, but it is not expected to endure into the next generation due to the above-mentioned topological diversity. The evidence can be seen as today's large artificial intelligence graphic processing units (AI GPUs) have had to move to much larger bond line interfaces to enable bare die attachment to heat sinks in order to work, and packages are continuing to grow. Instead, this paradigm can be shifted, such that the impact of interfaces will be minimized by ensuring that all interfaces are thin, allowing for a sustainable design path into the future.

Using such integrated heat spreaders, the thermal budgets of the anticipated future, in excess of 4 W/mm², can be addressed with a packaging methodology based on first principles that will be able to truly scale with all of the advanced packaging directions that are expected to emerge in the next decades.

### Technical Plan

Thermal management has become a gating bottleneck of package design today, exacerbated by advanced packing approaches that introduce nonuniformity into the topology of these systems. Curvature and device to device tolerances in height oftentimes drive system designers to build margin into the thermal system design to accommodate this topological uncertainty. Building on the traditional approach of employing compression in a thermal interface material (TIM) to makeup the topological uncertainty means that curvature has a multiplicative impact on thermal resistance. For example, a warpage of 300 micron requires an interface thickness of sometimes twice that, to allow the thermal interface material (TIM) to compress enough to enable full contact to the bow of the device at all points. This paradigm has historically driven a research focus on identifying ever increasing thermal conductivity interface materials to combat the temperature rises associated with these thicker bond lines.

Treating the thermal problem in such a way is inefficient and in the long run unsustainable, because material property advancement typically occurs on the order of years, which is mismatched to design cycles. When compared to the thermal conductivity of bulk materials, the conductivity of TIMs will always be expected to be lower due to the need for compression. Compliance arises from a low modulus, which generally derives from the composite nature of TIMs: typically a soft, low conductivity matrix filled with higher conductivity solids. Thus, one can quickly see that the drive towards ever increasing conductivity can have a confounding effect: the increase in conductivity results in stiffer thicker interface materials with less ability to not only conform to surface(s), but also less ability to reliably maintain contact over time as the package flexes (more stress and propensity to crack or delaminate).

Furthermore, relying on compression drives uncertainty into the assembly process.

Pressure drives compression, but topological variance drives an associated spatial variance in pressure that makes attaining consistent full contact, even in systems where the TIM should be compliant enough-somewhat inconsistent and unpredictable. As a result, TIMs today consume a substantial portion of the overall thermal budget. In idealized systems, the thermal budget for TIMs should be small, as seen in coupon level reports of TIM solutions that can achieve thermal resistances well below 5 mm²-° C./W. Translated into real systems, these impressive coupon resistances are typically several multiples higher.

In the plan discussed here, an approach to tackling this topological uncertainty, moving away from reliance on blind compression, and toward contouring the intersecting surfaces to match one another based on the known processing parameters that drive the warpage in fully packaged devices is detailed. Thus, the bond lines of the TIM can remain thin, with the low resistances that come along with such a configuration. Fundamentally this approach is about scale and modularity. Modification of geometry can be done quickly from product to product and generation to generation, as compared to material property modification, which is typically slow and oftentimes unsuccessful.

To achieve these goals, focus of the following development activity will be pursued:
1. Development and use of design models to predict the warpage windows of generic products as a function of temperature and IHS/heat sink fastening load so the intersecting devices (e.g. IHS) can be contoured to the predicted geometry.
2. The device intersecting surface of the IHS should ideally be contoured to the predicted geometry of the warped components, with sufficient precision and understanding to not only map to the device's cold curvature, but also to accommodate the change on topology as the device heats and cools during operation.
3. Thermal interfacing layers can be integrated with the contoured surfaces so that they can be coupled to the heat generating devices/components, allowing for accommodation of surface roughness and coefficient of thermal expansion (CTE) driven changes in warpage when the devices/components are in operation.
4. Integration of fluidic cooling structures into the topside of the IHS in order to produce a fully integrated, monolithic IHS with direct to lid cooling to demonstrate the potential of the approach.
5. Performance and reliability of the coupled devices to validate and to ensure that these ultra-thin, high-performance interfaces, survive the dynamic nature of device operation.

Regarding task 1 above, predictions of the median warpage of advanced packages from first principles can be made, considering both the material properties of the various components within the package, as well as conditions under which the components are assembled. When multiple dies of different thicknesses are assembled on the substrate, the resulting warped geometry of the package will be dependent on the thickness of the substrate and the dies, the material properties of the substrate and the dies, the standoff height, diameter, and pitch of die-to-substrate interconnects, as well as whether the dies are underfilled. Thus, when multiple dies of different form factors are assembled on a substrate, the resulting structure will not have a uniform curvature but will create a landscape with different curvatures. To be able to predict such multiply curved sections, the thermo-mechanical models can take into consideration the assembly process profiles, temperature-, time-, and direction-dependent thermo-physical properties of materials, and the geometry and dimensions of various elements in the packaging configuration.

Some variance from the analytical expectation is expected, as evidenced by the part-to-part variance that exists today across production lots. As such, predicted warpage profiles can be validated quantitatively using measurement tools, including, for example, shadow moire and optical CMM which are known in the art for measuring surface deformations and warpage in microelectronic packages. Validation will be used in part for iterative refinement of the models, but also to establish uncertainty windows for the predicted device geometries. These uncertainty windows will feed directly into tasks 2 and 3 to define the tolerance between the device and IHS geometry that will be accommodated by the thermal interface material. The target devices will be a combination of functional devices received from the marketplace and thermal test vehicles that will be fabricated under this development activity for performance validation.

The thermo-mechanical structural models will provide not only as built room-temperature warpage profiles, but also an understanding of how the device curvature changes as a function of operating temperature. Understanding the change in warpage is important because it incorporates a temporal parameter into the geometric uncertainty window, which can be accommodated in tasks 2 and 3.

In addition to warpage, packaging tolerances that drive non planarity, such as chiplet to chiplet height, underfill, and device attach variance, and heterogenous integration will also be considered.

The predicted topologies will feed directly into task 2, where the intersecting surfaces of the integrated heat spreaders will be contoured to map to the geometries identified in task 1. To achieve the surface contouring, 3D additive manufacturing will be employed to build targeted structures onto the surface of the IHS substrates (conventional substrates such as copper (such as high-purity copper, 99.99% copper), as well as advanced substrates, such as Ag Diamond) as well as onto aligned carbon nanotube substrates (task 3) to produce structures that monolithically integrate a TIM and IHS into a single, interface free, device cap. The deposition process will, in these examples, employ electrochemical additive manufacturing (ECAM) capability to produce micron scale resolution, massively scalable, 3D printing of metals, such as copper and copper alloys at room temperature.

In phase 1, the contoured IHS will be coupled to the device interface using an aligned CNT TIM structure. On the device side of the IHS, an elastic thermal interfacing solution is important to enable consistent contact over the entirety of the operating temperature range of the device, as predicted by the model outputs of task 1. Vertically aligned (VA) CNT TIMs will provide this characteristic, as well as the ability to precisely define the interface thickness to match the as designed margin between the expected device warpage and the contour of the IHS, which can be determined according to task 1.

This workflow will follow several workstreams, as follows:
Topological Matching: Here, curved structures will be deposited onto IHS substrates using an ECAM process to match the warpage of target devices (concave/ovoid/saddle point, etc.) as defined in modeling outputs (see FIG. 1B). The IHS substrate material will be selected based on modeling outputs, with the selection matrix being selected from traditional high conductivity metals like copper, as well as lower CTE metal composites, like metal diamond composites. The deposited curvature will be designed to minimize the required gap filling thickness of the TIM, which is generally the lowest conductivity portion of the thermal stack up. The geometry will be sized to ensure that the TIM can accommodate the surface roughness of the IHS-device interface, along with the change in geometry that will occur due to device heating and cooling in operation.
Power Density Matching: Bond line thickness minimization structures (e.g. chiplet or functional block sized pillars) will be deposited on to IHS substrates that minimize bond line thickness (BLT) specifically in the vicinity of higher power chiplets (see FIG. 8). This approach builds on the understanding that even in the high average power density packages, there will be localized hotspots that have power densities that are perhaps several multiples higher than the overall average power density. It is in the vicinity of these hotspots that it is most imperative that the bond line (and associated thermal resistance) be kept as small as possible.
Modulus Matching: This optional variant on the approach builds on the concept of building compressibility into the interfacing structure, however here the compression arises from selective design instead of excess margin. The modulus of the IHS will be modified by building lattice structure(s) directly onto the IHS so that it can conform to the device topology without precise upfront understanding of the actual curvature (see FIG. 1D). This deposited compressible/conformable layer within the IHS substrate will enable field fit of lid to a device with warpage that is undetermined in geometry but bounded in magnitude. Notable for this approach, the design parameters for the compressible/conformable layer need not be arbitrary, where the magnitude of nonplanarity can be informed by the model outputs of task 1, which will define the thickness of the compressible/conformable layer.

Generative design software (e.g., nTop) will be employed to design such IHS structures, which balances modulus and thermal conductivity of the compressible/conformable layer. While this approach lends itself to the more traditional compression-based approach of driving contact, it differentiates itself from that strategy through the ability to rapidly scale and locally modify the properties of the structure based on known inputs utilizing a software based approach (i.e., a generative design).

In task 3 thermal interfacing layers will be monolithically integrated into the IHS structures produced through the design work achieved in task 2. Here, the identified structure types will be deposited directly onto the substrate (i.e., metal foil with VACNTs on the opposing side). Such vertically aligned nanotubes are typically procuded on aluminum substrates, but a switch to copper to match the deposited structure material will be pursued. While deposition on aluminum is possible, switching to copper will eliminate/reduce the risk of galvanic corrosion or other reliability challenges that could arise from mating dissimilar metals at the interface layer. Using a single sided 20 um interface will produce a thermal resistance of about 3 mm²-C/W can readily be achieved, however, an end goal of demonstrating 1.5 mm²-C/W resistances in real, integrated applications will be pursued.

Fully integrated, the IHS structure will look like: TIM substrate>Contact structure>Bulk material all deposited continuously to produce a monolithic IHS structure with a fully integrated thermal interface (see FIG. 1D). While integrating the thermal interface is not required to take advantage of the topological matching achieved of the IHS, it represents a desirable combination of performance and integration simplicity for the end user.

Moving to task 4, this fully integrated structure allows as a final demonstration a completely monolithically integrated, direct-to-lid cooled thermal solution. Here, an additional (optional) layer will be built on the back of the IHS including fluidic routing channels to produce not just a monolithic IHS but instead a full cold plate that takes advantages of the topological matching capability, while also eliminating the second thermal interface between the IHS and cold plate that exists elsewhere. While the nominal output of this plan is a simple smooth flat interface that can be coupled to a variety of cold plates, it remains valuable to demonstrate the performance advantage that can be gained from inserting this optional last layer of integration, so that system designers can choose their approach intelligently.

The cold plate design will follow the fluid-to-fluid spot-to-spreader (F2/S2) design previously demonstrated by the Fedorov group (Green, C., Fedorov, A. G., and Joshi, Y. K. (Apr. 3, 2009). “Fluid-to-Fluid Spot-to-Spreader (F2/S2) Hybrid Heat Sink for Integrated Chip-Level and Hot Spot-Level Thermal Management.” ASME. J. Electron. Packag. June 2009; 131(2):025002) with a capability of dissipating hotspots up to 10 W/mm², but at the time was limited by traditional manufacturing capabilities addressed here with the ECAM process. See FIG. 9. The design will utilize two dedicated fluidic streams for background and hotspot heat fluxes to maximize temperature uniformity with minimal pressure drop. This strategy will be most powerful when coupled to the power density matched structures of task 2, as targeted hotspot cooling is most effective when a low resistance thermal circuit exists all the way from the hotspot to the elevated heat transfer coefficient structures at the cold plate level.

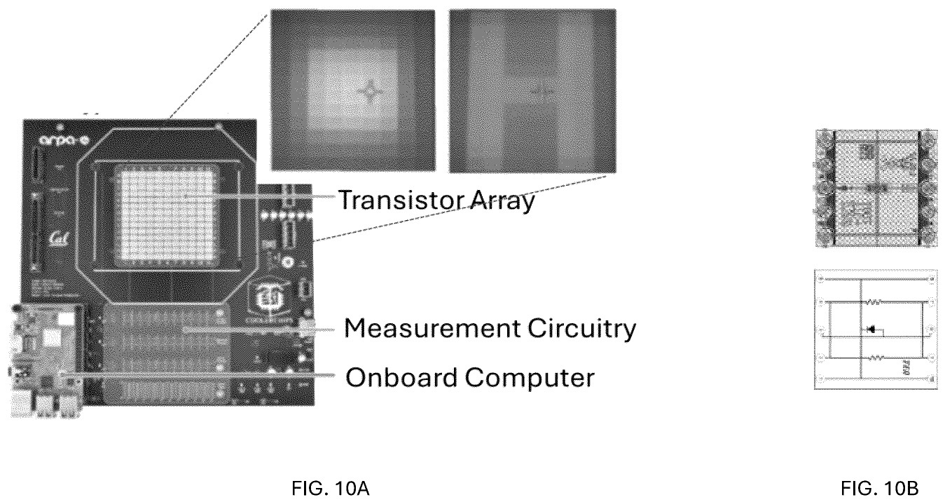

Lastly, task 5 will focus on validation of the performance and reliability of the IHS structures of tasks 1-4. To ensure the solution is relevant to the scale down/scale out and 3D HI program drivers, the techniques will be validated on packages representing the major advanced packaging strategies: fan out, 2.5D and 3D HI. Much of the thermal and mechanical characterization will be executed on thermal test vehicles (TTVs) built to represent the geometry, mechanics, and thermal profiles of each of these advanced packaging nodes. A bifurcated approach to TTV development will be pursued to de-risk characterization bottlenecks due to TTV availability, inaccuracies, or approximations. The Pilawa-Podgurski group (UC Berkeley) has developed a TTV platform with a novel structure that is amenable to representing the geometry (scalable to any desired package size), mechanics (flexible in substrate and PCB material selection) and power maps (up to 256 discrete hotspot “pixels”) of the target device. See FIG. 10A. All the TTV circuitry required to perform measurements and temperature estimations is included on one PCB. It provides a simple, highly flexible approach for TTV design, enabling rapid validation with high mechanical fidelity. Furthermore, its use of commercial electronic components allows for a low cost which is well suited to both nondestructive and destructive testing for validating reliability and performance.

In parallel, utility silicon chiplets with in situ temperature sensing and heating elements, with a target power density of >4 W/mm² will be used for evaluation. See FIG. 10B. Non-uniform power distribution across the chiplet can be achieved through the control of the circuitry, and the chiplet may include a redistribution layer and through silicon vias for stacking. Chiplets can be packaged in various substrate/interposer/fan-out configurations for interconnection with the circuitry.

With the structured IHS assembled to the TTV die, validation of the effectiveness of the topologically matched structures through contact area and contact pressure mapping using C-SAM, as well as Tekscan force, and pressure mapping tools can be performed. Validation of not just as designed contact, but also how contact varies as a function of temperature and through thermal cycling will be pursued. Evaluation of reliability and thermal performance through continuous 100-hour operation at 85° C., as well as through power cycling at 1,000 cycle intervals will be performed. Thermal performance of each device will be tracked via on chip or on-board temperature detectors, with no external instrumentation required. After testing, select devices will be cross-sectioned to evaluate changes in contact due to delamination cracking or other failure modes.

The feedback loop from experimental performance will include further review of interface performance (aerial nanotube density, height and encapsulant), IHS topology, and composition of the additively deposited conformal layer to maximize performance as a function of these parameters. Moving beyond TTVs, such IHSs can be attached to a functional bare die server to demonstrate performance in a relevant environment exercised in a Data Center Lab.

Overall, the technical plan detailed herein is expected to produce IHS structures and ultimately a design paradigm that enables dissipation of power densities in excess of 4 W/mm² while also maintaining an ability to simply and reliably couple cold plates to the heat spreading structures with predictable and consistently low thermal resistances.

Unless defined otherwise, all technical and scientific terms used herein have the same meanings as commonly understood by one of skill in the art to which the disclosed invention belongs. Publications cited herein and the materials for which they are cited are specifically incorporated by reference.

Those skilled in the art will recognize, or be able to ascertain using no more than routine experimentation, many equivalents to the specific instances of the invention described herein. Such equivalents are intended to be encompassed by the following claims.

1. A heat dissipation device comprising:
a substrate comprising a first surface and a second surface, which are on opposing sides of the substrate;
a thermal interfacial material or thermal interfacial coating in direct contact with at least part of the first surface; and
a heat dissipation structure in direct contact with the second surface;
wherein thermal resistance between the substrate, the thermal interfacial material or thermal interfacial coating, and the heat dissipation structure is in a range from between about 0.01 to 0.1 cm² ° C./W.

2. The device of claim 1, wherein the first surface comprises one or more non-planar features thereon to contact or maximize contact to one or more non-planar surfaces or curvatures present on a heat source; and wherein at least the one or more non-planar features include the thermal interfacial material or thermal interfacial coating thereon;
wherein the one or more non-planar surfaces or curvatures on the heat source optionally comprise ovoid, concave, saddle point, and/or stepwise features.

3. The device of claim 1, wherein the first surface is contoured to contact or maximize contact to one or more non-planar surfaces or curvatures present on a heat source.

4. (canceled)

5. (canceled)

6. The device of claim 1, wherein the heat dissipation structure comprises a compressible or conformable layer therein that provides local modulus reduction and is able to conform to one or more non-planar surfaces or curvatures present on a heat source when compressed thereon;
wherein the one or more non-planar surfaces or curvatures on the heat source optionally comprise ovoid, concave, saddle point, and/or stepwise features.

7. The device of claim 6, wherein the compressible or conformable layer is formed of or comprises a lattice structure.

8. (canceled)

9. (canceled)

10. The device of claim 1, wherein the substrate is a foil optionally made of aluminum or copper; or wherein the substrate is made of diamond, AlSiC, Si, Silver Diamond, CuW, Cu Diamond, CuMo, graphite, alumina, AlN, Mo, MgSiC, steel, Ni, Ti, bronze, brass, Sn, Si, SiC, GaN, SiO₂, BN, or GaAs.

11. The device of claim 1, wherein the thermal interfacial material or thermal interfacial coating comprises a plurality of carbon nanostructures; and
wherein the plurality of carbon nanostructures is optionally an array or a sheet of carbon nanotubes which are optionally vertically aligned on the first surface.

12. (canceled)

13. The device of any one of claims 1-12, wherein the heat dissipation structure comprises a surface which can be coupled to a cold plate structure; and/or
wherein the heat dissipation structure comprises a cold plate structure integrated directly thereon; and
wherein the heat dissipation structure is optionally selected from the group consisting of a heat sink, a cold plate, a lid, a heat spreader, a water block, a radiator, a gap filler, a vapor chamber, a heat pipe, a wick, and combinations thereof.

14. (canceled)

15. (canceled)

16. The device of claim 1, wherein the substrate has a thickness in range from between about 10 um to 6 mm, 50-500 um, 100-1000 um, or 100 to 5,000 um; or
wherein the heat dissipation structure has a thickness in range from between about 250 um up to 5 cm; or
wherein the thermal interfacial material or thermal interfacial coating has a thickness in range from between about 5 um-100 um, or up to about 500 um, 1000 um, 2000 um, or up to 3 mm.

17. (canceled)

18. (canceled)

19. (canceled)

20. The device of claim 1, wherein the heat dissipation structure forms an interface-free bond with the second surface.

21. The device of claim 1, wherein the device has a total thermal resistance which is in a range from between about 0.01 to 0.1 cm² ° C./W.

22. A method of making a device according to claim 1, the method comprising the steps of:
(a) forming a thermal interfacial material or a thermal interfacial coating in direct contact onto a first surface of a substrate; and
(b) forming or bonding a heat dissipation structure in direct contact onto a second surface of the substrate;
wherein the first surface and the second surface are on opposing sides of the substrate;
wherein thermal resistance between the substrate, the thermal interfacial material or thermal interfacial coating, and the heat dissipation structure is in a range from between about 0.01 to 0.1 cm² ° C./W.

23. (canceled)

24. The method of claim 22, wherein the first surface comprises one or more non-planar features thereon to contact or maximize contact to one or more non-planar surfaces or curvatures present on a heat source; and wherein at least the one or more non-planar features include the thermal interfacial material or thermal interfacial coating thereon;
wherein the first surface is optionally contoured to contact or maximize contact to one or more non-planar surfaces or curvatures present on a heat source; or
wherein the one or more non-planar surfaces or curvatures on the heat source optionally comprise ovoid, concave, saddle point, and/or stepwise features.

25. (canceled)

26. (canceled)

27. (canceled)

28. A method of making a heat dissipation device the method comprising the steps of:
(a″) determining or predicting, such as by modeling, surface topology and/or curvature of a heat source prior to and during operation of the heat source;
(b″) forming a heat dissipation structure comprising a bottom surface with one or more non-planar surfaces or curvatures, to match the determined or predicted surface topology and/or curvature of the heat source prior to and/or during operation;
wherein the heat dissipation structure is directly formed on or bonded to a substrate comprising a thermal interfacial material or a thermal interfacial coating; and
wherein thermal resistance between the substrate, the thermal interfacial material or thermal interfacial coating, and the heat dissipation structure is in a range from between about 0.01 to 0.1 cm² ° C./W.

29. The method of claim 28, wherein the surface topology and/or curvature of the heat source comprises ovoid, concave, saddle point, and/or stepwise features; or
wherein the surface topology and/or curvature of the heat source result from warpage during operation of the heat source and the thermal interfacial material or thermal interfacial coating remains in full contact or substantially in contact with the surface topology and/or curvature of the heat source during operation.

30. (canceled)

31. The device of claim 22, wherein the heat dissipation structure comprises a compressible or conformable layer therein that provides local modulus reduction and is able to conform to one or more non-planar surfaces or curvatures present on a heat source when compressed thereon; and
wherein the compressible or conformable layer is optionally formed of or comprises a lattice structure.

32. (canceled)

33. (canceled)

34. (canceled)

35. (canceled)

36. The method of claim 22, wherein the heat dissipation structure is bonded onto the second surface by a process selected from the group consisting of welding, soldering, sintering, brazing, fusion bonding, diffusion bonding, direct bonding, hybrid bonding, and combinations thereof; and
wherein the bonding optionally forms an interface-free bond between the heat dissipation structure and the second surface.

37. (canceled)

38. (canceled)

39. (canceled)

40. (canceled)

41. The method of claim 22, wherein the thermal interfacial material or thermal interfacial coating comprises a plurality of carbon nanostructures, such as carbon nanotubes; and
wherein the plurality of carbon nanostructures is optionally an array or a sheet of carbon nanotubes which are optionally vertically aligned.

42. (canceled)

43. (canceled)

44. The device of claim 22, wherein the method further comprises a step of forming a cold plate structure onto the heat dissipation structure directly thereon; and
wherein the heat dissipation structure is optionally selected from the group consisting of a heat sink, a cold plate, a lid, a heat spreader, a water block, a radiator, a gap filler, a vapor chamber, a heat pipe, a wick, and combinations thereof.

45. (canceled)

46. (canceled)

47. (canceled)

48. (canceled)

49. A method of dissipating heat comprising the steps of:
(i) contacting the device of claim 1 to a heat source;
wherein the device increases dissipation of heat generated by the heat source by at least about 10%, as compared to dissipation of heat generated by the heat source in the absence of the device.

50. (canceled)

51. (canceled)

52. (canceled)

53. (canceled)

54. (canceled)
